(19) United States
(12) Patent Application Publication
(10) Pub. No.: US 2009/0114261 A1
(43) Pub. Date: May 7, 2009

(54) Edge Mountable Electrical Connection Assembly

(76) Inventors: Robert Stancel, Los Altos, CA (US); Jeremy H. Scholz, Sunnyvale, CA (US); Paul M. Adriani, Palo Alto, CA (US)

Correspondence Address: Director of IP, 5521 Hellyer Avenue, San Jose, CA, 95138, US

(21) Appl. No.: 12/202,030

(22) Filed: Aug. 29, 2008

Related U.S. Application Data
(63) Continuation-in-part of application No. 11/924,594, filed on Oct. 25, 2007.
Application No. 11/924,594 is a continuation-in-part of application No. 11/964,694, filed on Dec. 26, 2007.
Application No. 11/964,694 is a continuation-in-part of application No. 12/136,016, filed on Jun. 9, 2008, now abandoned.
(60) Provisional application No. 60/968,826, filed on Aug. 29, 2007.
(60) Provisional application No. 60/968,870, filed on Aug. 29, 2007.

(51) Int. Cl. H01L 31/042

(52) U.S. Cl. 136/244

(57) ABSTRACT

Methods and devices are provided for improved large-scale solar installations. In one embodiment, a photovoltaic module is provided comprising of a plurality of photovoltaic cells positioned between a transparent module layer and a backside module layer. The module includes a first electrical lead extending outward from an edge of the module from between the transparent module layer and the backside module layer, wherein the lead is couplable to an adjacent module without passing the lead through a central junction box or an opening in either the transparent module layer or the backside module layer. The module may include a second electrical lead extending outward from an edge of the module from between the transparent module layer and the backside module layer, wherein the lead is couplable to another adjacent module without passing the lead through a central junction box or an opening in either the transparent module layer or the backside module layer.

### CROSS REFERENCE TO RELATED APPLICATIONS

This application claims priority to U.S. Provisional Application Ser. No. 60/968,826 filed Aug. 29, 2007. This application also claims priority to U.S. Provisional Application Ser. No. 60/968,870 filed Aug. 29, 2007. This application is a continuation-in-part of U.S. patent application Ser. No. 11/924,594 filed Oct. 25, 2007, and is also U.S. a continuation-in-part of patent application Ser. No. 11/964,694 filed Dec. 26, 2007. This application is a continuation-in-part of U.S. patent application Ser. No. 12/136,016 filed Jun. 9, 2008. All of the foregoing applications are fully incorporated herein by reference for all purpose.

### FIELD OF THE INVENTION

This invention relates generally to photovoltaic devices, and more specifically, to solar cells and/or solar cell modules designed for large-scale electric power generating installations.

### BACKGROUND OF THE INVENTION

Solar cells and solar cell modules convert sunlight into electricity. Traditional solar cell modules are typically comprised of polycrystalline and/or monocrystalline silicon solar cells mounted on a support with a rigid glass top layer to provide environmental and structural protection to the underlying silicon based cells. This package is then typically mounted in a rigid aluminum or metal frame that supports the glass and provides attachment points for securing the solar module to the installation site. A host of other materials are also included to make the solar module functional. This may include junction boxes, bypass diodes, sealants, and/or multi-contact connectors used to complete the module and allow for electrical connection to other solar modules and/or electrical devices. Certainly, the use of traditional silicon solar cells with conventional module packaging is a safe, conservative choice based on well understood technology.

Drawbacks associated with traditional solar module package designs, however, have limited the ability to install large numbers of solar panels in a cost-effective manner. This is particularly true for large scale deployments where it is desirable to have large numbers of solar modules setup in a defined, dedicated area. Traditional solar module packaging comes with a great deal of redundancy and excess equipment cost. For example, a recent installation of conventional solar modules in Pocking, Germany deployed 57,912 monocrystalline and polycrystalline-based solar modules. This meant that there were also 57,912 junction boxes, 57,912 aluminum frames, untold meters of cablings, and numerous other components. These traditional module designs inherit a large number of legacy parts that hamper the ability of installers to rapidly and cost-efficiently deploy solar modules at a large scale.

Although subsidies and incentives have created some large solar-based electric power installations, the potential for greater numbers of these large solar-based electric power installations has not been fully realized. There remains substantial improvement that can be made to photovoltaic cells and photovoltaic modules that can greatly reduce their cost of manufacturing, increase their ease of installation, and create much greater market penetration and commercial adoption of such products, particularly for large scale installations.

### SUMMARY OF THE INVENTION

Embodiments of the present invention address at least some of the drawbacks set forth above. The present invention provides for the improved solar module designs that reduce manufacturing costs and redundant parts in each module. These improved module designs are well suited for installation at dedicated sites where redundant elements can be eliminated since some common elements or features may be shared by many modules. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. At least some of these and other objectives described herein will be met by various embodiments of the present invention.

In one embodiment of the present invention, a junction-boxless photovoltaic module is used comprising of a plurality of photovoltaic cells and a module support layer providing a mounting surface for the cells. The module has a first electrical lead extending outward from one of the photovoltaic cells, the lead coupled to an adjacent module without passing the lead through a junction box. The module may have a second electrical lead extending outward from one of the photovoltaic cells, the lead coupled to another adjacent module without passing the lead through a central junction box. Without central junction boxes, the module may use connectors along the edges of the modules which can substantially reduce the amount of wire or connector ribbon used for such connections.

In yet another embodiment of the present invention, a photovoltaic module is provided comprising of a plurality of photovoltaic cells positioned between a transparent module layer and a backside module layer. The module may include at least one electrical housing positioned along an edge of the module, wherein the housing is located beneath the transparent module layer and is positioned so as not to contact a front side surface of the transparent module layer. The housing allows electrical connection to the photovoltaic cells by way of a first electrical lead in the housing that extends outward from between the transparent module layer and the backside module layer. By way of example and not limitation, the module may be a frameless module. In some embodiments, there may be one or more electrical housing along the same or different edges of the module.

A further understanding of the nature and advantages of the invention will become apparent by reference to the remaining portions of the specification and drawings.

### BRIEF DESCRIPTION OF THE DRAWINGS

FIG. 1 is an exploded perspective view of a module according to one embodiment of the present invention.

FIG. 2 shows a cross-sectional view of the module of FIG. 1.

FIGS. 3 through 7B show cross-sectional views modules according to various embodiments of the present invention.

FIGS. 8 and 9 show top-down views of modules according to various embodiments of the present invention.

FIG. 10A through 11B show top-down views of modules according to various embodiments of the present invention.

FIG. 12 shows an exploded perspective view of an edge housing according to one embodiment of the present invention.

FIGS. 13-14B show various views of embodiments of an edge housing according to the present invention.

FIGS. 15A-15C show various views of embodiments of edge housings according to the present invention.

FIG. 17-22 show cross-sectional views of modules according to embodiments of the present invention.

FIGS. 23-27 show various views of embodiments of edge housings according to the present invention.

FIGS. 28 and 29 show various views of module supports according to the embodiments present invention.

FIG. 30 shows various features of modules and edge housings according to embodiments of the present invention.

FIGS. 31 and 32 show views of one embodiment of an edge housing according to the present invention.

FIGS. 33-35 show cross-sectional views of modules according to embodiments of the present invention.

FIGS. 36-40 are bottom-up views of staggered backside and front side module layers according to embodiments of the present invention.

FIGS. 41-44 show various embodiments of internal electrical connections according to various embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and, thus, the description includes both structures wherein a device possesses the anti-reflective film feature and structures wherein the anti-reflective film feature is not present.

### Photovoltaic Module

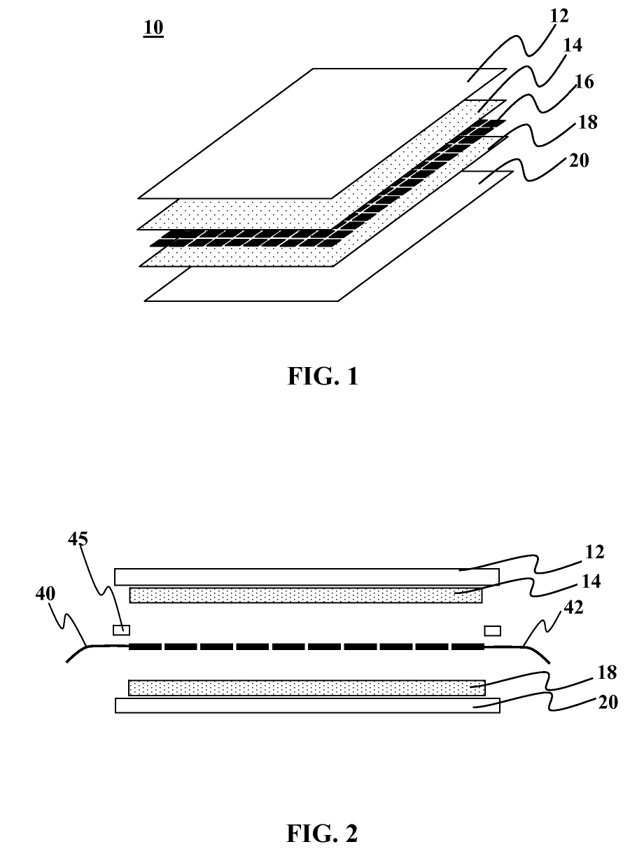

Referring now to FIG. 1, one embodiment of a module 10 according to the present invention will now be described. As module 10 is designed for large scale installation at sites dedicated for solar power generation, many features have been optimized to reduce cost and eliminate redundant parts. Traditional module packaging and system components were developed in the context of legacy cell technology and cost economics, which had previously led to very different panel and system design assumptions than those suited for increased product adoption and market penetration. The cost structure of solar modules includes both factors that scale with area and factors that are fixed per module. Module 10 is designed to minimize fixed cost per module and decrease the incremental cost of having more modules while maintaining substantially equivalent qualities in power conversion and module durability. In this present embodiment, the module 10 may include improvements to the backsheet, frame modifications, thickness modifications, and electrical connection modifications.

FIG. 1 shows that the present embodiment of module 10 may include a rigid transparent upper layer 12 followed by a pottant layer 14 and a plurality of solar cells 16. Below the layer of solar cells 16, there may be another pottant layer 18 of similar material to that found in pottant layer 14. Beneath the pottant layer 18 may be a layer of backsheet material 20. The transparent upper layer 12 provides structural support and acts as a protective barrier. By way of nonlimiting example, the transparent upper layer 12 may be a glass layer comprised of materials such as conventional glass, solar glass, high-light transmission glass with low iron content, standard light transmission glass with standard iron content, anti-glare finish glass, glass with a stippled surface, fully tempered glass, heat-strengthened glass, annealed glass, or combinations thereof. In one embodiment, the total thickness of the glass or multi-layer glass may be in the range of about 0.1 mm to about 13.0 mm, optionally from about 0.2 mm to about 12.0 mm. Optionally, the total thickness of the glass or multi-layer glass may be in the range of about 0.5 mm to about 2.0 mm, optionally from about 0.8 mm to about 1.5 mm. Optionally, the total thickness of the glass or multi-layer glass may be in the range of about 2.0 mm to about 13.0 mm, optionally from about 2.8 mm to about 12.0 mm. In one embodiment, the top layer 12 has a thickness of about 3.2 mm. In another embodiment, the backlayer 20 has a thickness of about 2.0 mm. As a nonlimiting example, the pottant layer 14 may be any of a variety of pottant materials such as but not limited to Tefzel®, ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, other materials of similar qualities, or combinations thereof. Optionally, some embodiments may have more than two pottant layers. The thickness of a pottant layer may be in the range of about 10 microns to about 1000 microns, optionally between about 25 microns to about 500 microns, and optionally between about 50 to about 250 microns. Others may have only one pottant layer (either layer 14 or layer 16). In one embodiment, the pottant layer 14 is about 75 microns in cross-sectional thickness. In another embodiment, the pottant layer 14 is about 50 microns in cross-sectional thickness. In yet another embodiment, the pottant layer 14 is about 25 microns in cross-sectional thickness. In a still further embodiment, the pottant layer 14 is about 10 microns in cross-sectional thickness. The pottant layer 14 may be solution coated over the cells or optionally applied as a sheet that is laid over cells under the transparent module layer 12.

It should be understood that the simplified module 10 is not limited to any particular type of solar cell. The solar cells 16 may be silicon-based or non-silicon based solar cells. By way of nonlimiting example the solar cells 16 may have absorber layers comprised of silicon (monocrystalline or polycrystalline), amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. Advantageously, thin-film solar cells have a substantially reduced thickness as compared to silicon-based cells. The decreased thickness and concurrent reduction in weight allows thin-film cells to form modules that are significantly thinner than silicon-based cells without substantial reduction in structural integrity (for modules of similar design).

The pottant layer 18 may be any of a variety of pottant materials such as but not limited to EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof as previously described for FIG. 1. The pottant layer 18 may be the same or different from the pottant layer 14. Further details about the pottant and other protective layers can be found in commonly assigned, co-pending U.S. patent application Ser. No. 11/462,359 (Attorney Docket No. NSL-090) filed Aug. 3, 2006 and fully incorporated herein by reference for all purposes. Further details on a heat sink coupled to the module can be found in commonly assigned, co-pending U.S. patent application Ser. No. 11/465,783 (Attorney Docket No. NSL-089) filed Aug. 18, 2006 and fully incorporated herein by reference for all purposes.

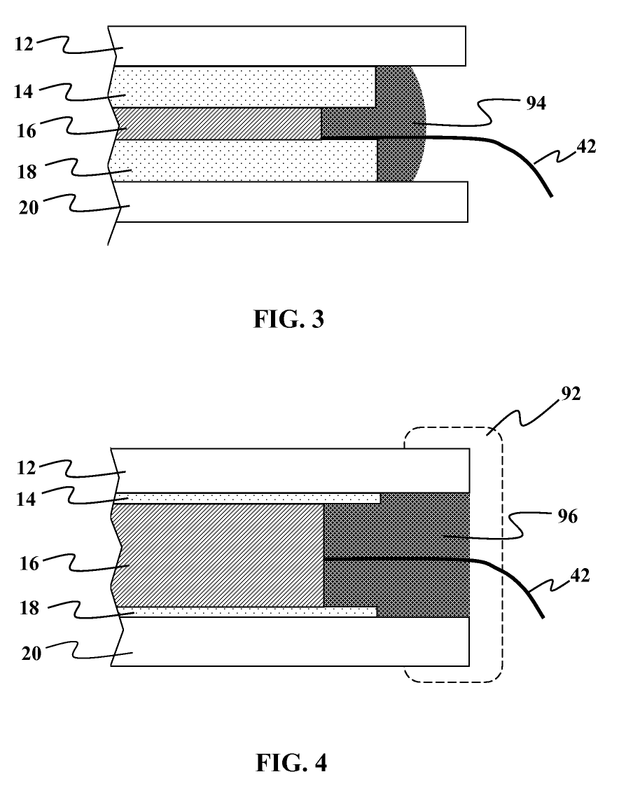

FIG. 2 shows a cross-sectional view of the module of FIG. 1. By way of nonlimiting example, the thicknesses of backsheet 20 may be in the range of about 10 microns to about 1000 microns, optionally about 20 microns to about 500 microns, or optionally about 25 to about 250 microns. Again, as seen for FIG. 2, this embodiment of module 10 is a frameless module without a central junction box. The present embodiment may use a simplified backsheet 20 that provides protective qualities to the underside of the module 10. As seen in FIG. 1, the module may use a rigid backsheet 20 comprised of a material such as but not limited to annealed glass, heat strengthened glass, tempered glass, flow glass, cast glass, or similar materials as previously mentioned. The rigid backsheet 20 may be made of the same or different glass used to form the upper transparent module layer 12. Optionally, in such a configuration, the top sheet 12 may be a flexible top sheet such as that set forth in U.S. Patent Application Ser. No. 60/806,096 (Attorney Docket No. NSL-085P) filed Jun. 28, 2006 and fully incorporated herein by reference for all purposes.

### Electrical Edge Connection

As seen in FIGS. 1 and 2, embodiments of the present invention minimize per-module costs and minimizes per-area costs by eliminating legacy components whose functions can be more elegantly addressed by improved mounting and wiring designs. By way of nonlimiting example as seen in FIGS. 1 and 2, one method of reducing cost and complexity is to provide edge exiting electrical connections, without the use of a central junction box. FIG. 1 shows that module 10 is designed to allow a wire or wire ribbon to extend outward from the module 10 or a solder connection to extend inward to a ribbon below. This outward extending wire or ribbon 40 or 42 may then be connected to another module, a solar cell in another module, and/or an electrical lead from another solar module to create an electrical interconnection between modules. Elimination of the junction box removes the requirement that all wires extend outward from one location on the module. Having multiple exit points allows those exits points to be moved closer to the objects they are connected to and this in turn results in significant savings in wire or ribbon length.

FIG. 2 shows a cross-sectional view of the junction box-less module 10 where the ribbons 40 and 42 are more easily visualized. The ribbon 40 may connect to a first cell in a series of electrically coupled cells and the ribbon 42 may connect to the last cell in the series of electrically coupled cells. Optionally, the wires or ribbons 40 and 42 may themselves have a coating or layer to electrically insulate themselves from the backsheet 20. FIG. 2 also shows that one of the pottant layers 14 or 18 may be optionally removed. The electrical lead wires/ribbons 40 and 42 may extend outward from between the top sheet 12 and the backsheet 20. In some embodiments, a moisture barrier 45 may be included to prevent moisture entry into the interior of the module. The moisture barrier 45 may optionally extend around the entire perimeter of the module or only along select portion. In one embodiment, the moisture barrier 45 may be about 5 mm to about 20 mm in width (not thickness) around the edges of the module. In one embodiment, the moisture barrier 45 may be butyl rubber, a zeolyte material, or other barrier material as described herein and may optionally be loaded with desiccant to provide enhanced moisture barrier qualities.

As seen in FIG. 3, connectors can also be designed to exit along the sides of the module, between the various layers 12 and 20, rather than through them. This simplifies the issue of having to form openings in hardened, brittle substrates such as glass which may be prone to breakage if the openings are improperly formed during such procedures. The solar cell 16 in FIG. 3 may be recessed so that moisture barrier material 94 may be applied along a substantial length of the edge of the module. This creates a longer seal area before moisture can reach the solar cell 16. The barrier material 94 may also act as a strain relief for the ribbon 42 extending outward from the module. By way of nonlimiting example, some suitable material for barrier material 94 include a high temperature thixotropic epoxy such as EPO-TEK® 353ND-T from Epoxy Technology, Inc., a ultraviolet curable epoxy such as EPO-TEK® OG 116-31, or a one component, non-conductive epoxy adhesive such as ECCOSEAL™ 7100 or ECCOSEAL™7200 from Emersion & Cuming. In one embodiment, the materials may have a water vapor permeation rate (WVPR) of no worse than about 5×10⁻⁴ g/m² day cm at 50° C. and 100% RH. In other embodiments, it may be about 4×10⁻⁴ g/m² day cm at 50° C. and 100% RH. In still other embodiments, it may be about 3×10⁻⁴ g/m² day cm at 50° C. and 100% RH. FIG. 3 also shows that the electrical lead 42 may extend from one side of the cell 16 (either top or bottom) and not necessarily from the middle.

Referring now to FIG. 4, it is shown that in other embodiments, barrier material 96 may extend from the solar cell 16 to the edge of the module and create an even longer moisture barrier area. The electrical lead 42 extends outward from the side of the module and the barrier material 96 may still act as an area of strain relief. FIG. 4 shows that in some embodiments, the solar cell 16 has a substantially larger cross-sectional thickness than the pottant layers 14 and/or 18. Some embodiments may have only one pottant layer. Other embodiments may have no pottant layers.

For any of the embodiments herein, a perimeter seal 92 (shown in phantom) may optionally be applied around the module 10 to improve the barrier seal along the side perimeter of the module. This perimeter seal 92 will reinforce the barrier properties along the sides of the module 10 and prevent sideway entry of fluid into the module. The seal 92 may be comprised of one or more of the following materials such as but not limited to desiccant loaded versions of EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof. By way of nonlimiting example, the desiccant may be selected from porous internal surface area particle of aluminosilicates, aluminophosphosilicates, or similar material. It should be understood that the seal 92 may be applied to any of the modules described herein to reinforce their barrier properties. In some embodiments, the seal 92 may also act as strain relief for ribbons, wires, or other elements exiting the module. Optionally, the seal 92 may also be used to house certain components such as bypass diodes or the like which may be embedded in the seal material.

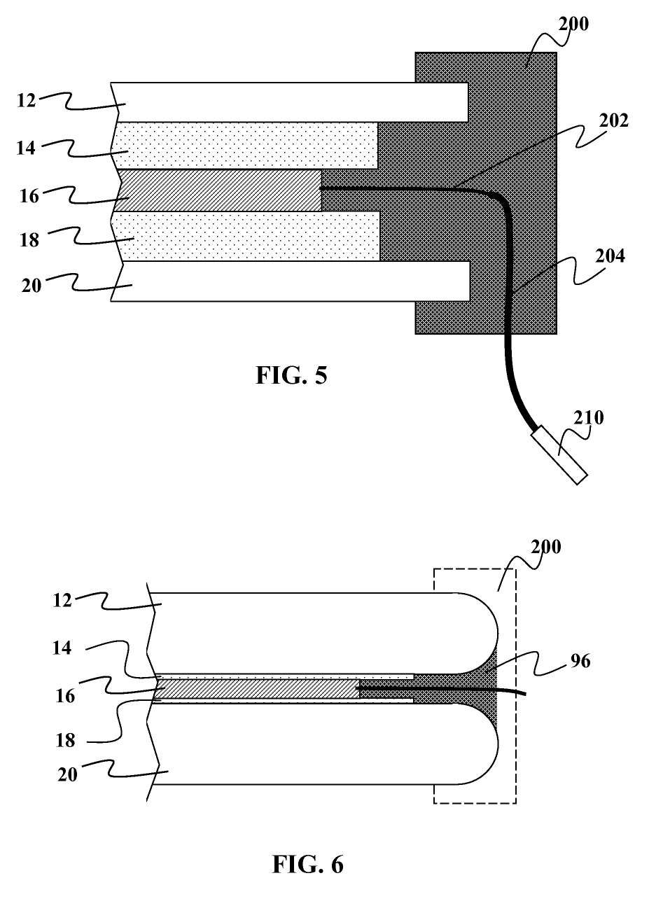

FIG. 5 shows a vertical cross-section of the module that may include a rigid transparent upper layer 12 followed by a pottant layer 14 and a plurality of solar cells 16. Below the layer of solar cells 16, there may be another pottant layer 18 of similar material to that found in pottant layer 14. A rigid backsheet 62 such as but not limited to a glass layer may also be included. FIG. 5 shows that an improved moisture barrier and strain relief element 200 may be included at the location where the electrical connector lead away from the module. As seen in FIG. 5, in some embodiments, a transition from a flat wire 202 to a round wire 204 may also occur in the element 200. Optionally, instead of and/or in conjunction with the shape change, transition of material may also occur. By way of nonlimiting example, the transition may be aluminum-to-copper, copper-to-aluminum, aluminum-to-aluminum (high flex), or other metal to metal transitions. Of course, the wire 204 outside of the moisture barrier and strain relief element 200 is preferably electrically insulated.

FIG. 5 also shows that a solder sleeve 210 may also be used with the present invention to join two electrical connectors together. The solder sleeve 210 may be available from companies such as Tyco Electronics. The solder sleeve may include solder and flux at the center of the tube, with hot melt adhesive collars at the ends of the tube. When heated to sufficient temperature by a heat gun, the heat shrink nature of the solder sleeve 210 will compress the connectors while also soldering the connectors together. The hot melt adhesive and the heat shrink nature of the material will then hold the connectors together after cooling. This may simplify on-site connection of electrical connectors and provide the desired weatherproofing/moisture barrier.

FIG. 6 shows that for some embodiments of the present invention, the upper layer 12 and back sheet 62 are significantly thicker than the solar cells 16 and pottant layers 14 or 18. The layers 12 and 62 may be in the range of about 2.0 to about 4.0 mm thick. In other embodiments, the layers may be in the range of about 2.5 to about 3.5 mm thick. The layer 12 may be a layer of solar glass while the layer 62 may be layer of non-solar glass such as tempered glass. In some embodiments, the layer 12 may be thicker than the layer 62 or vice versa. The edges of the layers 12 and 62 may also be rounded so that the any moisture barrier material 96. The curved nature of the edges provides more surface area for the material 96 to bond against.

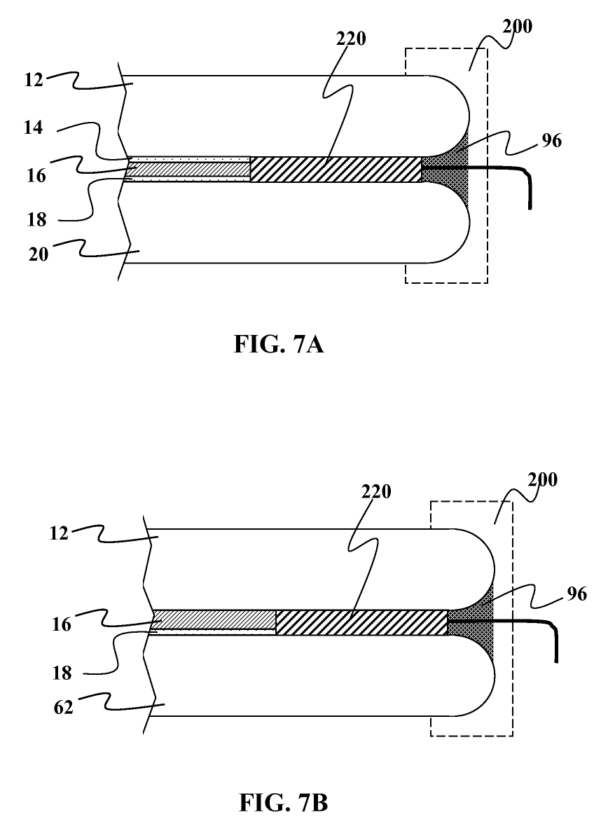

FIG. 7A shows an embodiment wherein edge tape 220 is included along the entire perimeter of the module to provide weatherproofing and moisture barrier qualities to the module. In one embodiment, the edge tape may be about 5 mm to about 20 mm in width (not thickness) around the edges of the module. In one embodiment, the tape may be butyl tape and may optionally be loaded with desiccant to provide enhanced moisture barrier qualities.

FIG. 7B shows a substantially similar embodiment to that in FIG. 7A except that the solar cell 16 is formed directly on one of the support layers. In FIG. 7B, the solar cell 16 is formed directly on the top transparent module layer 12. Optionally, the solar 16 maybe formed directly on the bottom layer

### Module Interconnection

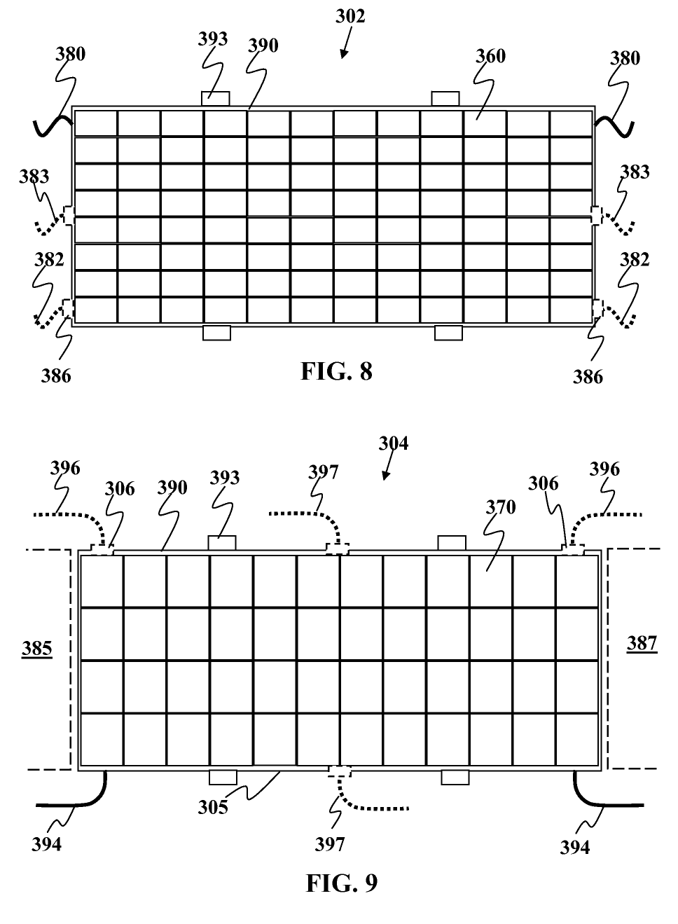

Referring now to FIG. 8, embodiments of the modules 302 used with the above assemblies will be described in further detail. FIG. 8 shows one embodiment of the module 302 with a plurality of solar cells 360 mounted therein. In one embodiment, the cells 360 are serially mounted inside the module packaging. In other embodiments, strings of cells 360 may be connected in series connections with other cells in that string, while string-to-string connections may be in parallel. FIG. 9 shows an embodiment of module 302 with 96 solar cells 360 mounted therein. The solar cells 360 may be of various sizes. In this present embodiment, the cells 360 are about 135.0 mm by about 81.8 mm. As for the module itself, the outer dimensions may range from about 1660 mm to about 1665.7 by about 700 mm to about 705.71 mm. Optionally, the active area dimensions may range from about 1660 mm to about 1665.7 by about 700 mm to about 705.71 mm. Optionally, the module may have outer dimensions in the range of about 1 m by about 2 m. Optionally, the module may have dimensions of the active area in the range of about 1 m by about 2 m. Optionally, in other embodiments, the solar modules each have a weight less than about 35 kg (optionally about 31 kg or less) and a length between about 1900 mm and about 1970 mm, and a width between about 1000 mm and about 1070 mm. Optionally, in other embodiments, the solar modules each have a weight less than about 28 kg (optionally about 25 kg or less) and a length between about 1900 mm and about 1970 mm, and a width between about 1000 mm and about 1070 mm.

FIG. 9 shows yet another embodiment of module 304 wherein a plurality of solar cells 370 are mounted there. Again, the cells 370 may all be serially coupled inside the module packaging. Alternatively, strings of cells may be connected in series connections with other cells in that string, while string-to-string connections may be in parallel. FIG. 9 shows an embodiment of module 302 with 48 solar cells 370 mounted therein. The cells 370 in the module 304 are of larger dimensions. Having fewer cells of larger dimension may reduce the amount of space used in the module 302 that would otherwise be allocated for spacing between solar cells. The cells 370 in the present embodiment have dimensions of about 135 mm by about 164 mm. Again for the module itself, the outer dimensions may range from about 1660 mm to about 1666 mm by about 700 mm to about 706 mm.

The ability of the cells 360 and 370 to be sized to fit into the modules 302 or 304 is in part due to the ability to customize the sizes of the cells. In one embodiment, the cells in the present invention may be non-silicon based cells such as but not limited to thin-film solar cells that may be sized as desired while still providing a certain total output. For example, the module 302 of the present size may still provide at least 100 W of power at AM1.5G exposure. Optionally, the module 302 may also provide at least 5 amp of current and at least 21 volts of voltage at AM1.5G exposure. Details of some suitable cells can be found in U.S. patent application Ser. No. 11/362,266 filed Feb. 23, 2006, and Ser. No. 11/207,157 filed Aug. 16, 2005, both of which are fully incorporated herein by reference for all purposes. In one embodiment, cells 370 weigh less than 14 grams and cells 360 weigh less than 7 grams. Total module weight may be less than about 16 kg. In another embodiment, the module weight may be less than about 18 kg. Further details of suitable modules may be found in commonly assigned, co-pending U.S. patent application Ser. No. 11/537,657 filed Oct. 1, 2006, fully incorporated herein by reference for all purposes. Industry standard mount clips 393 may also be included with each module to attach the module to support rails.

Although not limited to the following, the modules of FIGS. 8 and/or 9 may also include other features besides the variations in cell size. For example, the modules may be configured for a landscape orientation and may have connectors 380 that extend from two separate exit locations, each of the locations located near the edge of each module. In one embodiment, that may charged as two opposing exit connectors on opposite corners or edges of the module in landscape mode, without the use of additional cabling as is common in traditional modules and systems. Optionally, each of the modules 302 may also include a border 390 around all of the cells to provide spacing for weatherproof striping and moisture barrier.

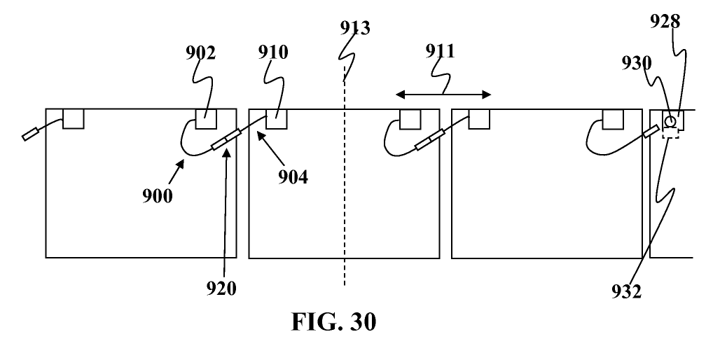

Referring still to FIGS. 8 and 9, it should be understood that removal of the central junction box, in addition to reducing cost, also changes module design to enable novel methods for electrical interconnection between modules. As seen in FIG. 8, instead of having all wires and electrical connectors extending out of a single central junction box that is typically located near the center of the module, wires and ribbons from the module 302 may now extend outward from along the edges of the module, closest to adjacent modules. The solar cells in module 302 are shown wherein first and last cells are electrically connected to cells in adjacent modules. Because the leads may exit the module close to the adjacent module without having to be routed to a central junction box, this substantially shortens the length of wire or ribbon need to connect one module to the other. The length of a connector 380 may be in the range of about 5 mm to about 500 mm, about 5 mm to about 250 mm, about 10 mm to about 200 mm or no more than 3× the distance between the closest edges of adjacent modules. Some embodiments have wire or ribbon lengths no more than about 2× the distance between the edges of adjacent modules. Some embodiments have wire or ribbon lengths no more than about 2× the distance between a junction box or edge housing on module and a junction box or edge housing on another module. Some embodiments have wire or ribbon lengths no more than the distance from the edge of the module to the center of the module. Some embodiments have wire or ribbon lengths no more than ¾ distance from the edge of the module to the center of the module. Some embodiments have wire or ribbon lengths no more than ½ the distance from the edge of the module to the center of the module. Some embodiments have connectors of the same length. Others may have connectors where one is longer, but the other is shorter. In these asymmetric designs, the combined of lengths of the wires from one module to an adjacent module would be less the length of module would be less than the length of the module in that axis along which the wires are extended to be connected. If the modules are rectangular and oriented to be connected in landscape orientation, the total length of the two wires would be less than the long axis (length) of the module. If the modules are to be connected in portrait orientation, the combined wire lengths would be less than short axis (the width) of the module. Optionally, in some embodiments, the combined lengths of the two wires would be less than 90% of the length of the module along the axis of connection. Optionally, in some embodiments, the combined lengths of the two wires would be less than 80% of the length of the module along the axis of connection. Optionally, in some embodiments, the combined lengths of the two wires would be less than 70% of the length of the module along the axis of connection. Optionally, in some embodiments, the combined lengths of the two wires would be less than 60% of the length of the module along the axis of connection. Optionally, in some embodiments, the combined lengths of the two wires would be less than 50% of the length of the module along the axis of connection. This is also shown in FIG. 30 which shows an axis of connection 911. These lengths traditionally would not work as a central junction box in the center of the module would require a wire longer than the distance just to reach the module edge. These short distance wires or ribbons may substantially decrease the cost of having many modules coupled together in close proximity, as would be the case at electrical utility installations designed for solar-based power generation.

By way of nonlimiting example, the connector 380 may comprise of copper, aluminum, copper alloys, aluminum alloys, tin, tin-silver, tin-lead, solder material, nickel, gold, silver, noble metals, or combinations thereof. These materials may also be present as coatings to provide improved electrical contact. Although not limited to the following, in one embodiment, a tool may use a soldering technique to join the electrical leads together at the installation site. Optionally, in other embodiments, techniques such as but not limited to welding, spot welding, reflow soldering, ultrasonic welding, arc welding, cold welding, laser welding, induction welding, or combinations thereof may be used. Soldering may involve using solder paste and/or solder wire with built-in flux.

As seen in FIG. 8, some embodiments may locate the connectors 382 (shown in phantom) at a different location on the short dimension end of the module 302. Optionally, an edge housing 306 (shown in phantom) may also be used with either connectors 380 or 382 to secure the connectors to module 302 and to provide a more robust moisture barrier. Optionally, as seen in FIG. 8, some embodiments may have the edge housing 383 extending closer to the mid-line of the short dimension end of the module.

FIG. 9 shows one variation on where the connectors exit the module 304. The connectors 394 are shown to exit the module 304 along the side 305 of the module with the long dimension. However, the exits on this long dimension end are located close to ends of the module with the short dimensions, away from the centerpoint of the module. This location of the exit on the long dimension may allow for closer end-to-end horizontal spacing of modules with the ends of adjacent modules 385 and 387 (shown in phantom) while still allowing sufficient clearance for the connectors 394 without excessive bending or pinching of wire therein. As seen in FIG. 9, other embodiments of the present invention may have connectors 396 (shown in phantom) which are located on the other long dimension side of the module 304. Optionally, some embodiments may have one connector on one long dimension and another connector on the other long dimension side of the module (i.e. kitty corner configuration). In still further embodiments, a connecter 397 may optionally be used on the long dimension of the module, closer to the midline of that side of the module. As seen in FIG. 9, edge housings 306 (shown in phantom) may also be used with any of the connectors shown on module 304.

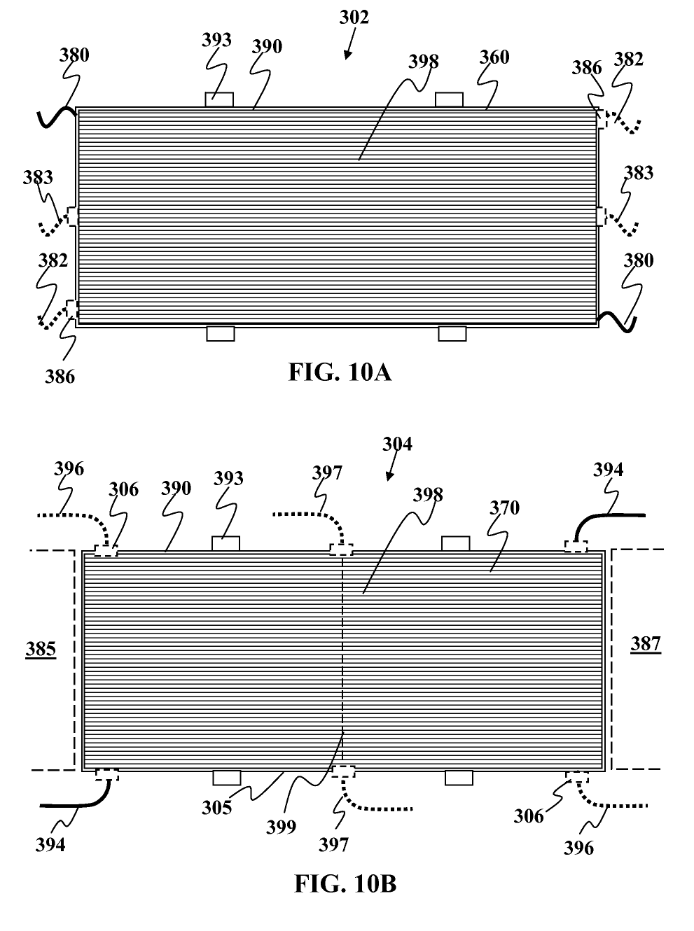

Referring now to FIGS. 10A and 10B, it is shown that the connectors of FIGS. 8 and 9 may be adapted for use with solar cells 398 of other configurations. FIG. 10A shows that the solar cells 398 are of extremely long, elongate configuration. In one embodiment, each solar cell 398 may run the length of the module within the area surrounded by the edge tape moisture barriers. These elongate cells may be coupled to have electrical leads extending outward from any of the positions shown in the two figures. In one embodiment, both electrical leads are on the same side of module. In another embodiment, they are on different sides. In a still further embodiment, they are diagonal from each other. In yet another embodiment, they are on opposing sides. FIG. 10B shows that the elongate cells 398 may be strung together by one or more centerline connector(s) positioned along the midline 399.

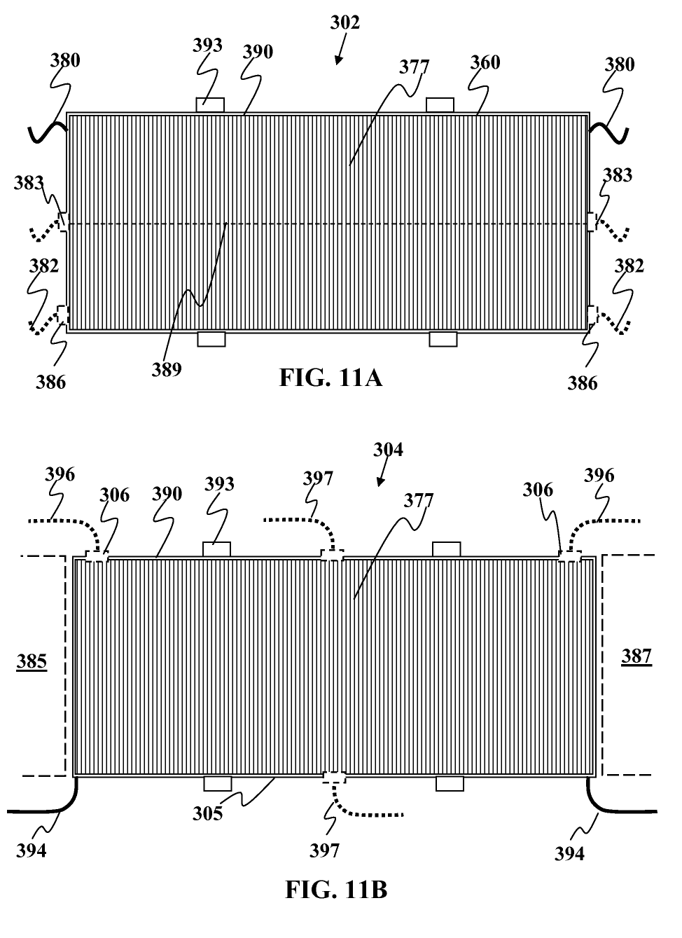

Referring now to FIGS. 11A and 11B, it is shown that the connectors of FIGS. 8 and 9 may be adapted for use with solar cells 377 of other configurations. In this embodiment, the cells 377 extend substantially across the width of the module (between the moisture barrier, if there is one) along the shorter length of the module. Cells 398 of FIGS. 10A and 10B extend across the width of the module (between the moisture barrier, if there is one) along the longer length of the module. FIG. 11A shows that in one embodiment, elongate cells 377 may be strung together by one or more centerline connector(s) positioned along the midline 389. The edge housings 383 are used. By way of example and not limitation, typically only one set of edge housings are used such as two edge housing 383, two edge housings 386, one edge housing 383 with one edge housing 386, etc. . . . It should be understood that in any of these embodiments, the edge housing may be completely on the backside of the module and does not extend beyond the glass perimeter. Optionally, other embodiments may have then extend beyond the glass perimeter.

FIG. 11B also shows that in some embodiments, the edge housing 306 may be positioned not to be exactly at the position next to the last cell. FIG. 11B shows that the housing 306 remains close the last cell but positioned to be spaced apart from it.

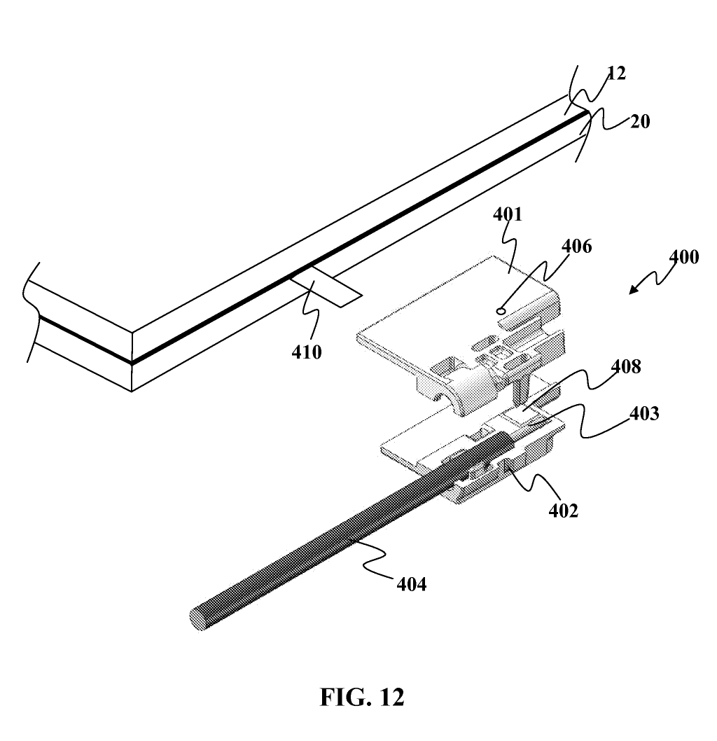

Referring now to FIG. 12, yet another embodiment of the present invention will now be described. FIG. 12 provides a more detailed description of an edge housing 400 that enables the electrical connection of one electrical conductor to another at the edge of a multilayer flat panel or module while providing electrical, environmental, and mechanical protection to both cables. The housing 400 wraps around the edge of the solar module at the location of the electrical lead exit and is bonded to the module layers at all points surrounding the conductor exit, providing an environmental seal, and mechanical support for the edge housing 400. In the present embodiment, the edge housing 400 includes an upper half 401 and a lower half 402. The edge housing 400 may optionally have a set screw or other means of providing mechanical pressure to electrically connect the two bare conductors within the module. The second conductor 403 is mechanically connected to the edge housing by means of a compression fitting or adhesive. The second conductor 403 may be a round wire with an insulating layer 404. Entry and exit holes 406 for the injection of a potting or encapsulating material exist in the module, providing an environmental seal to the conductor junction. The housing 400 may define a cavity 408 for receiving the electrical lead 410 and to provide room for encapsulating material.

Using the edge as an exit area for the electrical lead in a solar module provides several cost advantages due to not requiring any holes to be cut in the glass or potting material. However, in this method the edge sealant for the module is breached by the conductor which makes environmentally sealing the edge of the panel difficult. The present embodiment of the invention provides an insulated electrical joint and mechanical strain relief for the second cable leading away from the edge housing. This advantageously allows for the transition of a flat wire to round wire. In addition to providing a method for sealing and securing an edge exiting flat conductor, the present embodiment of the invention provides a housing that is easy to assembly in an automated many by providing locating and retaining features for the two conductors involved in the connection.

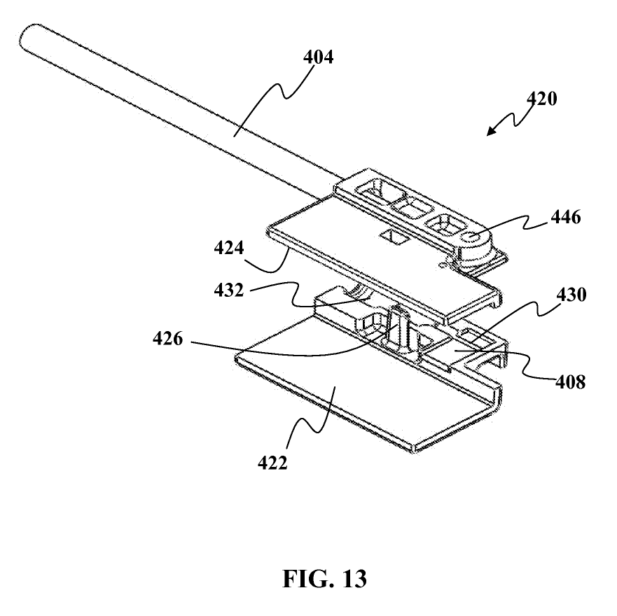

Referring now to the embodiment of FIG. 13, several features of the edge housing 420 will be described in more detail. Two large sealing and bonding surfaces 422 and 424 allow the housing 420 to be bonded to the planar portions of the module. Retention features for the two housings are also included. This may involve tabs 426 to hold the two halves together. Optionally, a snap feature is provided to hold the two halves of the edge housing 420 together. A cavity 430 is provided within the housing 420 to receive the round wire 403. The cavity 432 may be shaped to mechanically compress or pinch certain areas along the wire insulation 404 for retention purposes. A feature is provided in the housing to provide mechanical pressure on the joint between the two electrical contacts, ensuring an electrical connection. This may be accomplished in terms of sizing the cavity 408 and 430 to provide the desired mechanical compression when the halves of the edge housing are brought together. Additionally, the connecter 420 defines therein a channel connecting all open space within the module so as to be potted with a moisture barrier compound. In one embodiment, this allows a housing to be formed without air therein once potting material is injected into the channel.

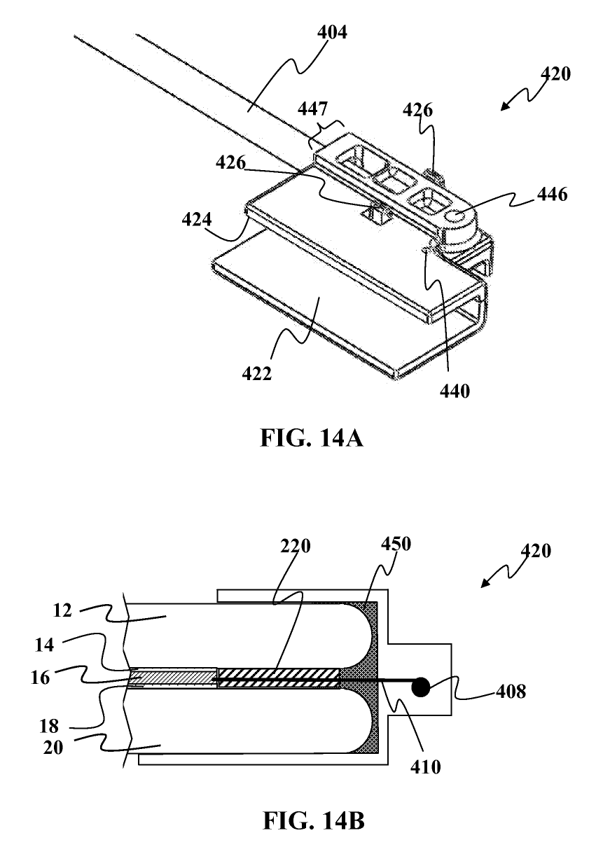

FIG. 14A shows the embodiment of FIG. 13 when the two halves of the housing 420 are brought together. The halves may brought together first and then positioned to engage the module. Optionally, one half may first be adhered to the module and positioned so that the electrical lead is in the cavity 408. Then the second half of the housing 420 is then engaged to complete the housing and attach it to the module. In one embodiment, the two halves of housing 420 comprises of two injection molded parts which can be connected by a mechanical snap mechanism, and locate relative to one another via a locating feature. The body contains a hole 440 in which to inject potting material to fill any air space around the flat electrical conductor exiting the solar panel. The body is also breached by a threaded hole 446 into which a screw can be inserted so as to apply mechanical pressure to the joint between the two conductors. The body will also contain a feature allowing strain relief to the exiting cable. It should be understood that the upper portion 447 may be reduced in height to be flush with the upper piece that provides support surface 424.

As seen in FIG. 14B, this housing 420 will prevent water vapor from entering a breach in the edge of a multilayer solar panel, allowing the edge to be used as an electrical conductor exit. The open spaces in the housing 420 are filled with potting material 450 to form a moisture barrier therein. The potting material 450 may be injected into the housing 420 through opening 440 after the housing 420 is mounted onto the module or optionally before mounting. The housing 420 may be configured so that the potting material will have increased surface area contact with the module and present a long pathway for any moisture trying to enter into the module. The housing 420 may be designed to prevent damage to the cells by moisture ingress, provide mechanical strain relief to the exiting cable, and enable fast, easy manufacture of the solar panel.

Although not limited to the following, the potting material 450 may be comprised of one or more of the following: Tru-seal®, ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, other materials of similar qualities, or combinations thereof.

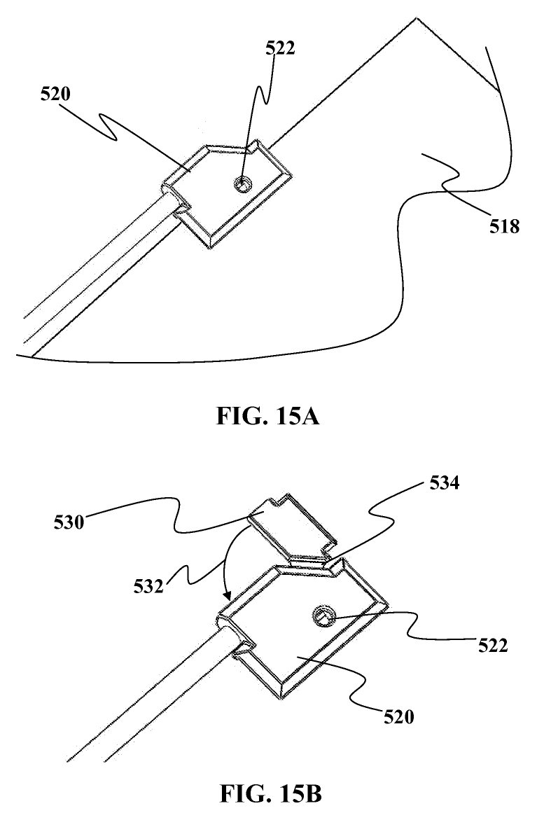

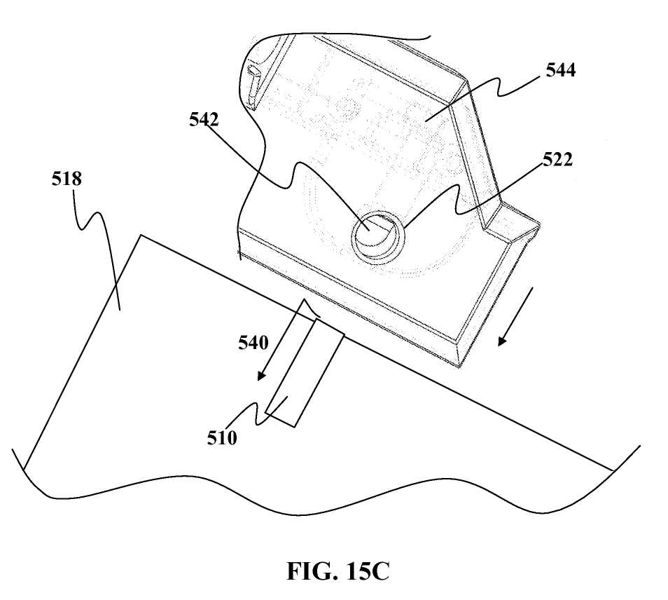

Referring now to FIG. 15A, yet another embodiment of the edge housing 420 will be described. This housing is coupled to the edge of the module and may be single piece device as more clearly seen in FIG. 15B. An opening 422 may be provided on the edge housing 420 to allow for infusion of pottant or adhesive into the housing. The opening 422 may also allow for soldering or welding of electrical leads that are housed inside the housing 420.

FIG. 15B shows how the edge housing 420 can be formed as a single piece unit with a flap portion 430 that can be folded over to clamp against an opposing surface of the housing 420. Arrow 432 shows how the opposing portion 430 may be folded about the hinge 434 to clamp against the other surface of the housing 420 in a clam-shell fashion.

FIG. 15C show a close-up view of edge housing 420. The housing 420 may slide over the module 418 and overlap the electrical lead 410. In this embodiment, the electrical 410 may extend out the edge and is then wrapped over a planar surface of the module 418. This folded configuration is indicated by arrow 440. The electrical lead may then be in contact with metal tab 442 inside the edge housing 420. In the present embodiment, the tab 422 (partially shown in phantom) extends inside the housing 420 to coupled to a wire leading outside the housing to connect to another module. The tab 422 maybe curved at a opposite end 444 to connect with the wire. The opening 422 allows the metal tab 442 to be soldered, welded, or otherwise electrically coupled t the electrical lead 410 coming from the module. The connection between the electrical lead 410 and the tab 442 may be made before or after the edge housing is placed on the module. It should be understood than the edge housing 420 may also be adapted for use with glass-glass type modules as set forth in U.S. Patent Application Ser. No. 60/862,979 filed Oct. 25, 2006.

### Underside Edge Housing

Referring now to FIG. 16, yet another embodiment of an edge housing according to the present invention will now be described. FIG. 16 shows that this embodiment of the edge housing 600 is positioned where the housing is located beneath the transparent module layer 602 and is positioned so as not to contact a front side surface 604 of the transparent module layer. In the present embodiment of the invention, the solar cells 606 are located between the transparent module layer 602 and an opposing module layer 608. It should be understood that various encapsulant layers may optionally be included between the cells and the layers 602 and 608 as are not shown for ease of illustration. In the present embodiment, a moisture barrier 610 may be included along the perimeter of the layer 608.

Although not limited to the following, the module layer 602 may be configured to be larger in at least one dimension, such as but not limited to width and/or length, relative to the corresponding module layer 608. This creates an overhang portion 612 that allows for the underside edge housing 600 to fit fully or partially thereunder. In one embodiment, this overhang portion 612 may be in the range of about 1 mm to about 15 mm. In another embodiment, this overhang portion 612 may be in the range of about 1 mm to about 50 mm. Optionally, in another embodiment, this overhang portion 612 is about 0.05% to about 2% of the module length along the same axis. Optionally, instead of having the entire module layer 608 be shorter than the module layer 602, only certain portions of the module layer 608 may be cut back or shaped to allow for the edge housing 600 to fit thereunder. The module layer 602 may have a thickness that is the same, thinner, or thicker than the thickness of module layer 608. The module layer 602 may comprise of a material that is the same or different from the material used in module layer 608. Some embodiments may be designed so that a portion of the edge housing 600 also contacts a side surface 613 of the upper transparent layer. Others may be designed not to contact the underside surface 609 of the layer 608.

Advantageously, positioning the edge housing 600 so that it does not contact a front side surface 604 of module layer 602 creates a substantially planar front surface that allows for easier snow or rain runoff. The lack of protrusions or projections on this surface facilitates cleaning as it also reduces the odds of dirt or snow collecting on the module surface and adding structural load to the module or undesirably shading the underlying cells 606. It should also be understood that the present configuration has the advantages of edge housing 600 not sticking out sideways beyond the perimeter of the module. This allows for the possibility for continuous extruded or otherwise formed seal between panels, such as but not limited to configurations with close vicinity of panels (see FIG. 20).

Another benefit of the embodiment comprises of the bulge 631 around 630 is recessed further from the peripheral edge of the module, so that insertion of the module into a C-cross section or similar profile is possible (with sufficient rubber grommeting). This allows for a thickness along the edge of the module that is reduced and allows for easier installation. The edge thickness in one embodiment may be less than or may be substantially similar to the thickness of all the module layers combined.

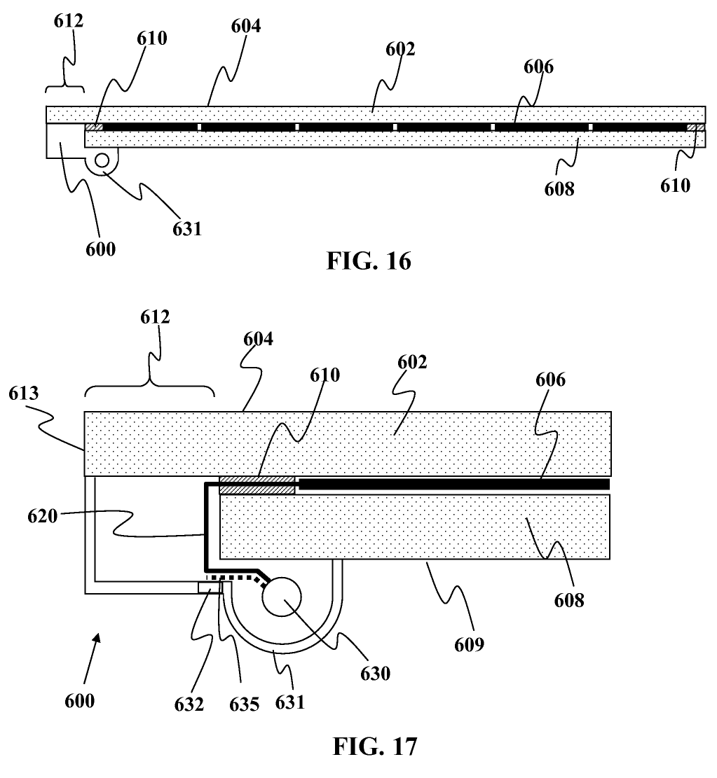

Referring now to FIG. 17, a close-up cross-sectional view of the edge housing 600 more clearly shows the elements therein. The metal connector 620 provides interconnection between the cells 606 through the moisture barrier 610 to the wire 630 that connects this module to an adjacent module. Although not limited to the following, the metal connector 620 may be comprised of aluminum with full or local plating that can be soldered (nickel, tin, copper). By way of nonlimiting example, the wire 630 may be comprised of copper, can also be plated, e.g. with tin for better solderability. The opening 632 is optional and allows for the injection of pottant, sealant, and or adhesive into the interior of the edge housing 600. Optionally, other methods for preventing moisture penetration may involve barriers such as but not limited to tape, sheet or extruded seal of moisture barrier material around the perimeter of the edge housing. As seen in FIG. 17, the electrical connection of metal connector 620 to wire 630 allows the cells in the module to be coupled to cells in an adjacent module. Optionally, a tab 633 (shown in phantom) from the wire 630 may be used to allow the metal connector 620 to connected together at a location spaced apart from the wire 630, such as but not limited to a position accessible through the opening 632.

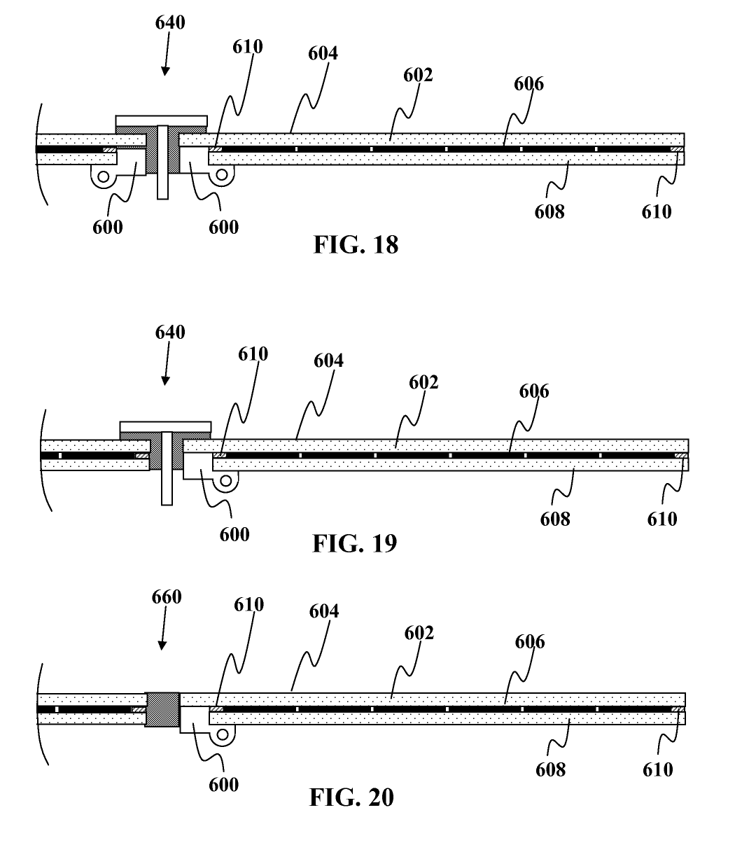

Referring now to FIG. 18, one embodiment of a module is shown connected to an adjacent module. The use of the underside mounted edge housing 600 allows the modules to be flush mounted against one another. A spacer or liner 640 may be included therebetween. This flush mounting is particularly useful for building facade or other mountings where it is desirable for aesthetic or weatherproofing reasons to have the modules closely joined as shown in FIG. 18.

FIG. 19 shows a variation on the embodiment of FIG. 18. In this embodiment, the adjacent module 650 presents one edge without an edge housing to mate with the module 601.

FIG. 20 shows a variation on the embodiment of FIG. 19. In this embodiment, the adjacent module 650 presents one edge without an edge housing to mate with the module 601. A simplified spacer or liner 660 is used that maintains a substantially flush surface between the modules 601 and 650. This provides a more even surface to provide for easier run-off of rain water and minimize debris buildup on the module surface. A smooth surface that minimizes protrusions also allows for easier cleaning and maintenance. Also, aesthetic considerations may be addressed with this configuration such as being a completely flush surface, e.g. of facade

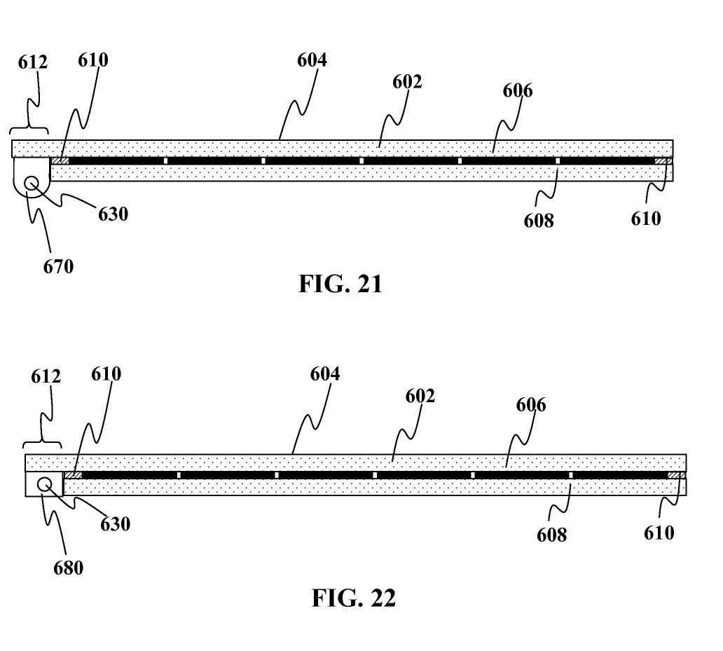

Referring now to FIG. 21, yet another embodiment of an underside edge housing 670 is shown. This embodiment of the edge housing 670 is designed not to contact the top side surface 604 of the module layer 602 and does not contact the underside surface 607 of the module layer 608. As seen in FIG. 22, the portion of connector 670 with wire 630 is located underneath the overhang portion 612 of module layer 602. This minimizes the portion of the connector 670 that ends over the surface to minimize its visual appearance and to provide a larger planar surface for mounting the module in general.

FIG. 22 shows a still further variation wherein the housing 680 is positioned completely under the overhang portion 612 and does not extend beyond the lower bounds defined by the underside surface 607. This configuration further minimizes the size envelope of the module and allows installations in more confined areas where having a smooth front side surface and backside surface is desirable.

It should be understood that for any of the foregoing embodiments, there may be one, two, or more housings on each module. Similar to those embodiments show in FIG. 8 through 11, there may be two housings per module. The two housings may be on the same edge of the module or different edges. Optionally, some may have more than two housings per module. Optionally, some may only one housing. One housing embodiments may be similar to a central junction box used in traditional modules in the sense that it will contact two electrical wires extending outward.

### Details of Underside Edge Housing

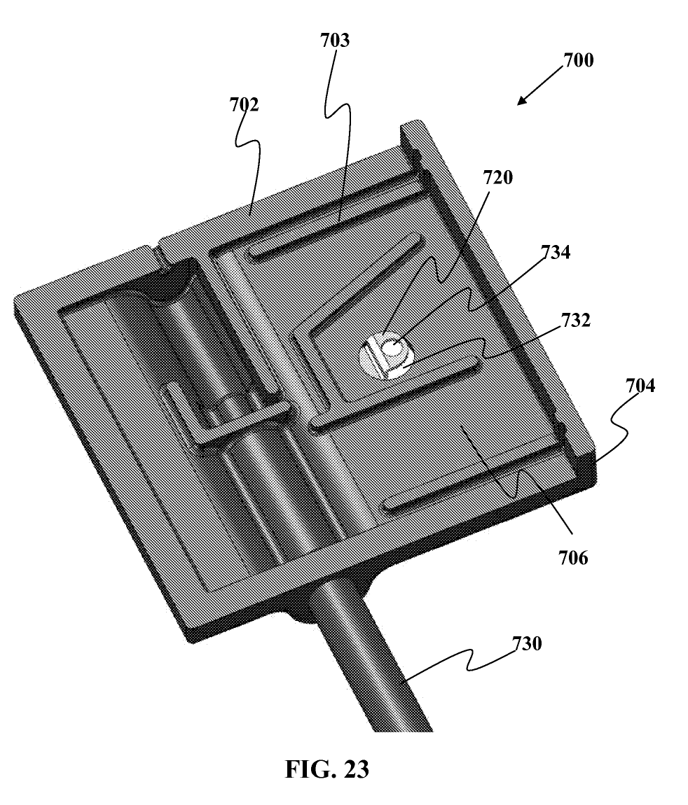

Referring now to FIG. 23, an exemplary embodiment of an underside edge housing 700 will now be described. As seen in FIG. 23, the edge housing 700 includes a surface 702 for engaging and underside of the module layer 608. The surface 702 may extend around the perimeter of the edge housing 700 to seal the housing 700 against the surface of the module layer 608. This will secure the housing 700 in place and minimize moisture entry into the module. This embodiment of the edge housing 700 may optionally include a lip 704 to engage a side surface of the module layer 608. Although not limited to the following, the thickness of lip 704 may be selected so that it does not extend between the outer module perimeter defined by the length or width of the module layer 602. Of course, it should be understood that some embodiment may be without any lip or upward extending surface to contact the side of module layer 602. A cavity 706 may be defined within the housing 700 by the perimeter surface 702 and the lip 704. The cavity 706 may be filled with potting material, adhesive material, insulating material, and/or other material to fill the cavity 706. An opening 708 may be provided to allow air or gas to escape as the cavity 706 is filled. The cavity 706 may be filled before, during, and/or after attachment of the housing 700 to the module layer 602 or module layer 608.

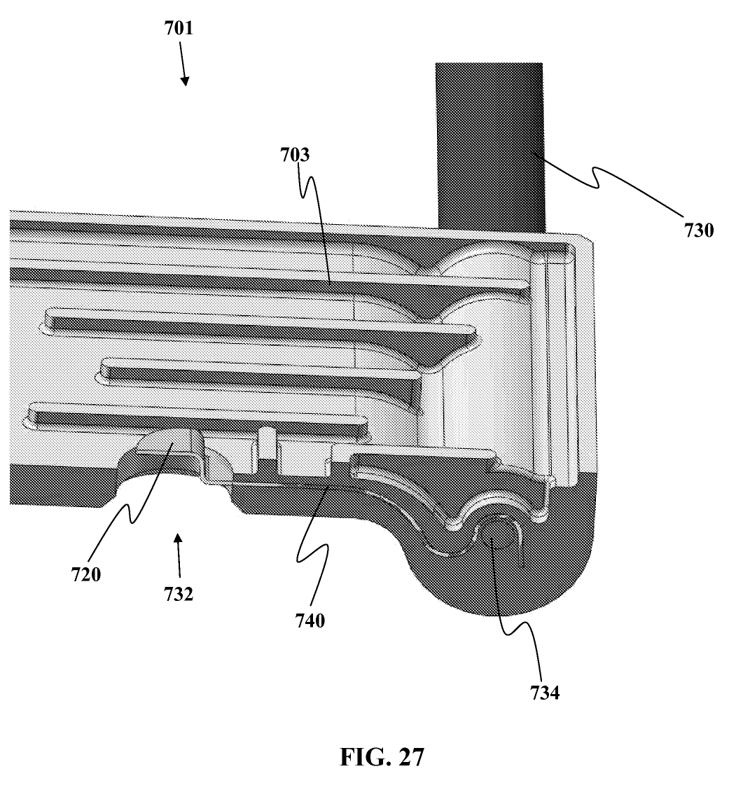

FIG. 23 also shows a metal connector 720 that will electrically connect the wire 730 to an electrical lead (not shown) connected to the cells inside the module. FIG. 23 shows that the metal connector 720 may be positioned over an opening 732. The metal connector 720 may itself include an opening 734 to allow for connection to the electrical lead from the module. Although not limited to the following, the opening 734 may be used for registering detail for holding tab during insert molding of the tab and cable assembly. Optionally in other embodiments of the present invention, the opening 734 may allow for better flow of solder between the tab and strip 620 when soldering them. Although not limited to the following, the metal connector 720 extends into the interior of the edge housing 700 to reach the core portion of wire 730. In other embodiments, the metal connector 720 is merely an interface to a wire or ribbon that leads to cells inside the module. With regards to the housing or edge housing, the edge housing 700 may be comprised of two pieces formed together. Optionally the edge housing 700 may be molded or formed around the wire 630 and metal connector 720 (FIG. 27 also shows additional details).

Referring still to FIG. 23, this embodiment of the edge housing 700 is shown with ribs 703. These ribs may be on the underside of the edge housing 700 or on other surfaces of the housing. In one embodiment, the ribs 703 are provided to guide flow of pottant material within the edge housing 700 before, during, or after manufacturing. It should be understood that the ribs 703 may be of various shapes such as but not limited to straight, curved, or combinations thereof to provide the desired flow of pottant material. The ribs 703 may also be designed to provide structural rigidity to the edge housing 700. The ribs may be solid or they may be hollow. Some embodiments may use ribs 703 close to the opening 732 to guide the flow of pottant material that may be introduced by that opening. Ribs may also be designed to guide flow for other opening or openings used with the edge housing 700.

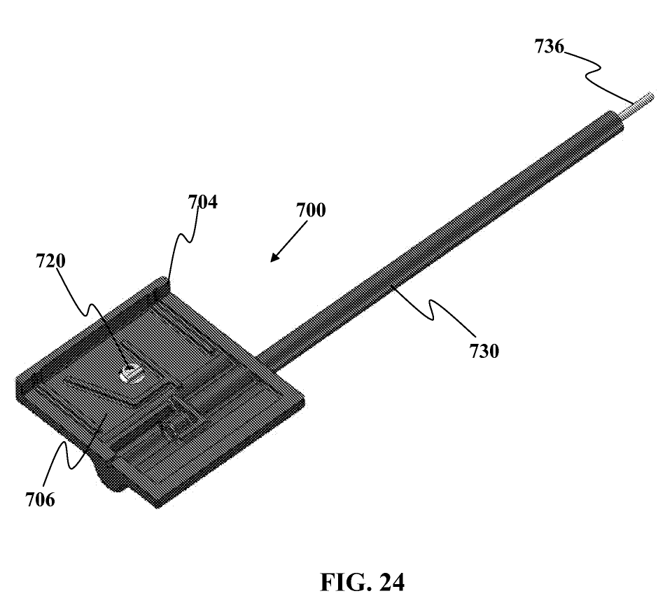

FIG. 24 shows another view of the edge housing 700. The core 736 of the wire 730 is more easily visualized in this figure. As seen in FIG. 24, the core 736 may extend to an interior area of the edge housing 700 where it will be coupled to the metal connector 720. Although not limited to the following, the interior of the edge housing 700 may be molded to hold the metal connector 720 in place.

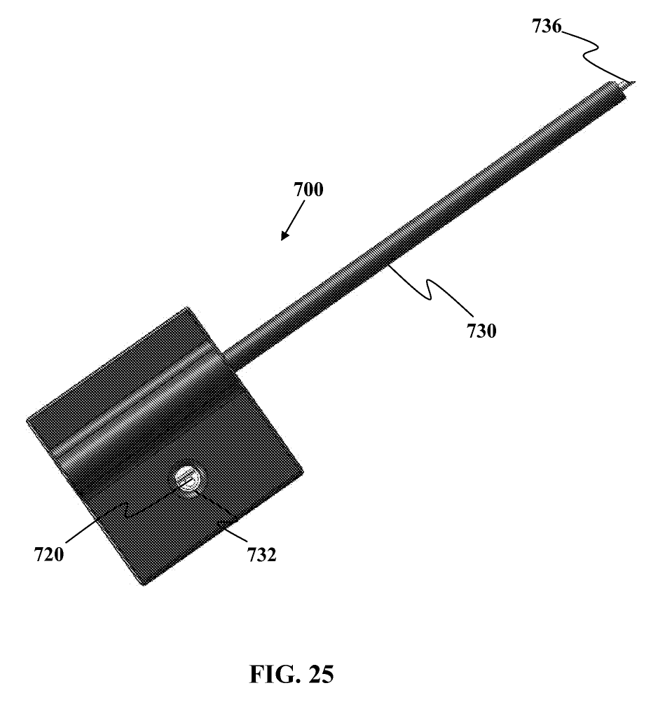

FIG. 25 shows an underside view of the edge housing 700. Again, the core 736 of the wire 730 is easily visualized. This underside view also shows the opening 732 through which the metal connector 720 is visible.

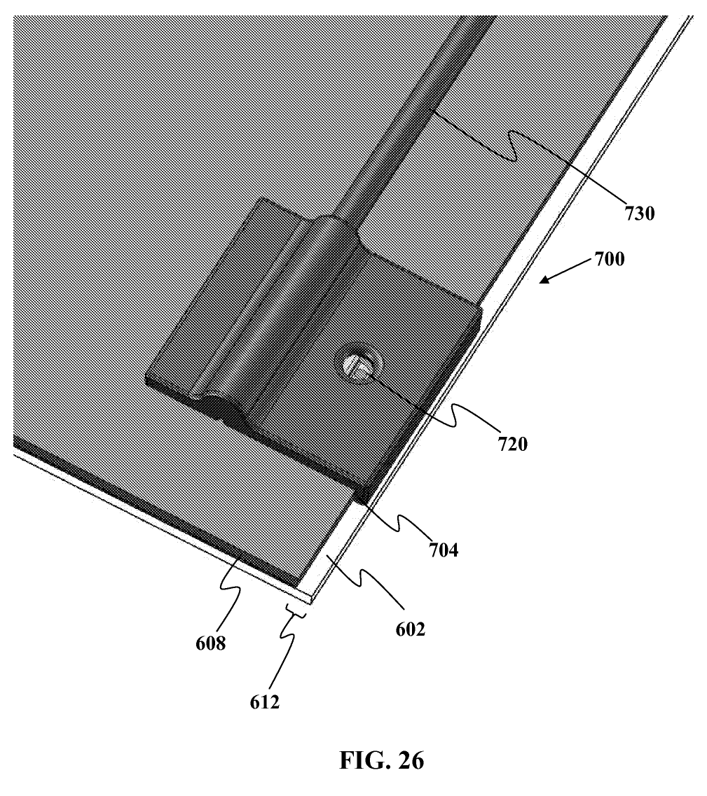

Referring now to FIG. 26, the underside edge housing 700 is shown as attached on to the underside of a module. FIG. 26 more clearly shows how this embodiment engages the layers of the module. It should be understood of course that this embodiment is purely exemplary and nonlimiting. The edge housing 700 is shown as substantially engaging the module layer 608 with surface 702 (see FIG. 23 for details). The lip 704 fully engages the side of module layer 608. The top of lip 704 may optionally engage the underside of module layer 602. The module layer 602 is shown as extending beyond the edge of the module layer 608 by a portion 612. The edge housing may fully occupy the overhang portion 612 or only a part of the overhang portion 612.

Referring now to FIG. 27, a cross-section is shown of an edge housing 701 according to one embodiment of the present invention. Edge housing 701 is substantially similar to edge housing 700, except for some variation in the support ribs in the cavity 706. This cross-sectional view shows how the metal connector 720 is connected to the core 734 of the wire 730. A channel 740 is defined in the edge housing to allow the metal connector 720 to reach the core 734. In one embodiment of the present invention, this channel 740 may be molded into the edge housing 701. Optionally, the channel 740 may be insert-molded, wherein the tab is mounted into the tool, and during molding material flows around it, encasing it. In another embodiment, the channel 740 is defined when a top portion of the edge housing 701 is brought into contact with a bottom portion of the edge housing 701. This may be via a clamshell or hinge type design. Optionally, this may include two separate pieces that are joined together to form the edge housing 701. FIG. 27 also shows that the ribs 703 may be extend upward from the recessed surface of the housing to provide contact surfaces to allow engagement of the edge housing at location within the outer perimeter of the housing.

### Shaped Module Mounts

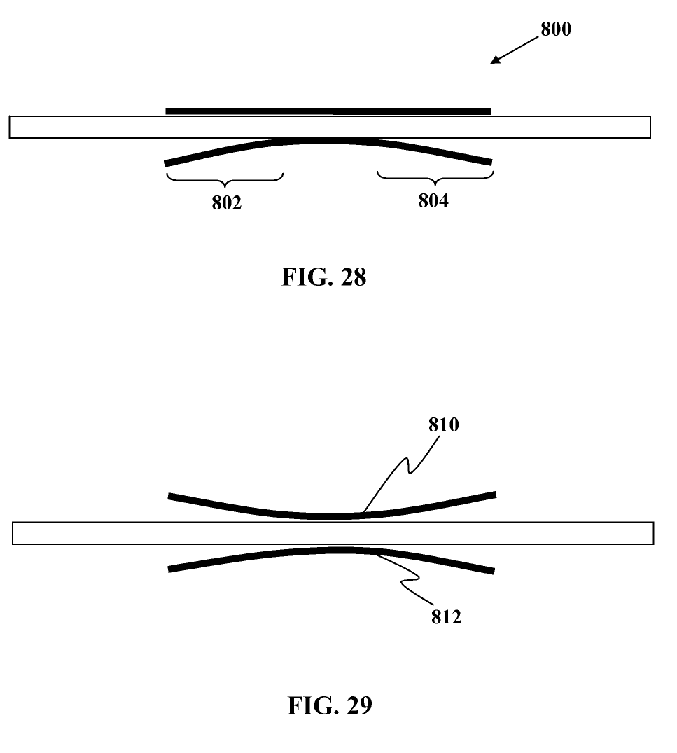

Referring now FIG. 28, one embodiment of a module clamp according to the present invention will now be described in more detail. As seen in FIG. 8, the module clamps 393 are used to secure the module to ground supports or roof mounts. Often times, the modules will be subject to mechanical loads caused by wind, hail, snow build-up, or human handling. Localized stress concentrations due to load and the interface of the module to the mount may cause more fragile layers in the module such as the glass layer(s) to crack. To minimize such localized stress concentrations, the module clamp 800 is shown with portions 802 and 804 of the clamp curved to allow for deflection of the module without creating stress concentration points. In this current embodiment, only the bottom surface of clamp 800 contains the curved surfaces. FIG. 29 shows an embodiments where both top and bottom surfaces 810 and 812 are curved. The amount of curvature varies depending on the particular application. In one embodiment, the radius of the curvature is constant or varying in the range of about 50 mm to about 500 mm, depending on the flexibility and thickness of the surface materials.

### Service Loop

Referring now to FIG. 30, another technique for connecting modules together will now be described. According to this embodiment of the present invention, the wire portion 900 of one housing 902 is of greater length than the wire portion 904 from another housing 910. This provides a “service loop” configuration. Furthermore, as seen in FIG. 30, although not limited to the following, the wires 900 and 904 exiting from the edge housings all exit from the same side of each housing (i.e. in this embodiment, from the left side of each housing). In this manner, there are not two different edge housing parts, but both housing have the cable exiting in the same orientation from the housing. Thus the wires 900 and 904 may be of different lengths, but the housings 902 and 910 are substantially similar. The differing lengths permit for a service loop configuration to accommodate variance in module spacing, protection of connector under panel rather between them (junction 920 is under the module), minimizes cable length, reduces forces on cable, and/or creates a rain drip-off point off-center, rather than where the connector is. The wires 900 and 904 may be permanently connected such as by soldering, welding, or the like. Optionally, the wires 900 and 904 may be coupled by releasable connections, such as but not limited to quick release connections, press-fit connection, plug connections, shaped/keyed connections, or the like.

FIG. 30 also shows that in some embodiments, the edge housing 928 may itself have an opening 930 and/or optionally a laterally oriented receptacle 932 (shown in phantom) to receive a connector at the end of wire 900. In this manner, no wire extends outward from the housing 928. Wire 900 is plugged directly into the housing through either the opening 930, laterally oriented receptacle 932, or some other receiver for the connector 920 of wire 900. Some embodiments of housing 928 may use only a single opening for a single connector 920.

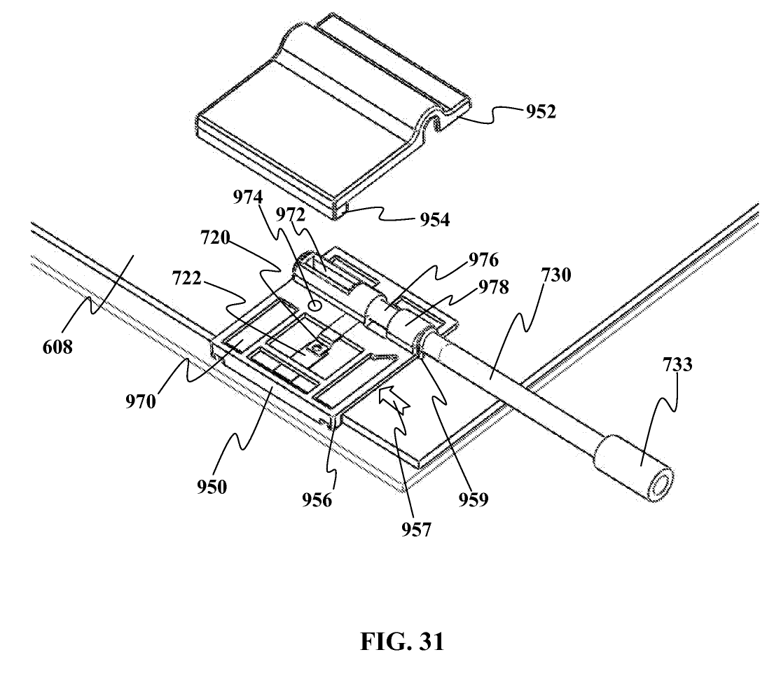

Referring now to FIG. 31, a still further embodiment of the present invention of an edge connector 940 will now be described. FIG. 31 shows that an internal portion 950 coupled to the module layer 608. An external shell 952 is coupled over the internal portion 950. Pottant, adhesive material, and/or other insulating material may be applied to the portion 950 and/or to the shell 952 when the two pieces are engaged. This two piece device may allow for more complete filling of the material inside the shell 952 without having to use high pressures. Some embodiments may come pre-loaded or pre-coated with pottant, adhesive material, and/or other insulating material on one or both pieces. Some embodiments may have material on one portion 950 with reacts with material in the other portion 952 to facilitate bonding and/or moisture sealing. Some may come with tape adhesive along the edges with release coating that can be pealed off to allow the adhesive tape to attach the parts together. In one embodiment, the internal portion 950 is affixed to the module with adhesive such as glue, dual sided tape, or similar material. Pottant is applied over the internal portion 950 and/or on the external shell 952. This advantageously speeds assembly as pottant can be easily applied and all pottant does not have to be forced through an opening on the external shell 952 which may require higher pressure.

Referring still to FIG. 31, this embodiment shows that the shell 952 may have a lip portion 954 to engage the “stepped” portion of the module. The interior portion 950 may also include a lip portion 956. In some embodiments, the lip on the outer shell 952 will touch the surface of the top glass, but the lip of the inner portion 950 does not to allow for flow of pottant there under. Optionally, the module may be without the “stepped” portion if the module layers are not offset and are of the same size. In that configuration, the lip portions 954 and 956 may be removed to allow for connection to a planar surface. As seen in FIG. 31, the tab 720 and electrical connector 722 may be joined together inside this edge connector 940. This may occur before, during or after attachment of the portion 950 to the module. Optionally, the tab 720 may be metal. Optionally, tab 720 may be shaped to flex downward and apply positive pressure to electrical connector 722 to allow for good contact. The wire 730 may also include a connector 733 to connect to a connector from a downstream, upstream, or adjacent module or device. It should also be understood that the device may be made of more than the two portions 950 and 952. Some embodiments may have three portions, four portions, five portions, or more. Some may have components that include part the upper portion and the interior portion. Not every edge connector on the module may be of the same design or number of portions/components. It should be understood that the internal portion 950 may have portions spaced apart to allow pottant to flow thereunder as indicated by arrow 957. By way of nonlimiting example, the spacing may be provided in the present embodiment by a tab 959.

In the present embodiment, openings 970 are provided to allow pottant to flow to contact the module and provide adhesion of components 950, 952, and internal elements therein to the module. There may be corresponding tabs, protrusions, or other members on the outer shell 952 to help direct and/or push pottant into these openings when the pieces are brought together. There may be a structure in the interior of the outer shell 952 that fits into opening 972 to assist in indexing or aligning the parts together. The fit with opening 972 may be loose or it may be an interference fit that helps to hold the two pieces 950 and 952 together and prevent spring back of the pottant inside the outer shell 952. Optionally, an opening 974 may be used to interference fit with one or more protrusions on the interior the outer shell 952 to help hold the pieces together while the pottant cures. By way of example, the pottant may be silicone, two-part silicone, EVA, other pottant material, or single or multiple combinations thereof. FIG. 31 also shows that optionally, the wire 730 may be exposed at location 976 to allow pottant to have direct contact to bond with the wire 730 to be a second barrier and to provide mechanical strength in case the wire 730 does not fully adhere to the internal portion 950 within structure 978.

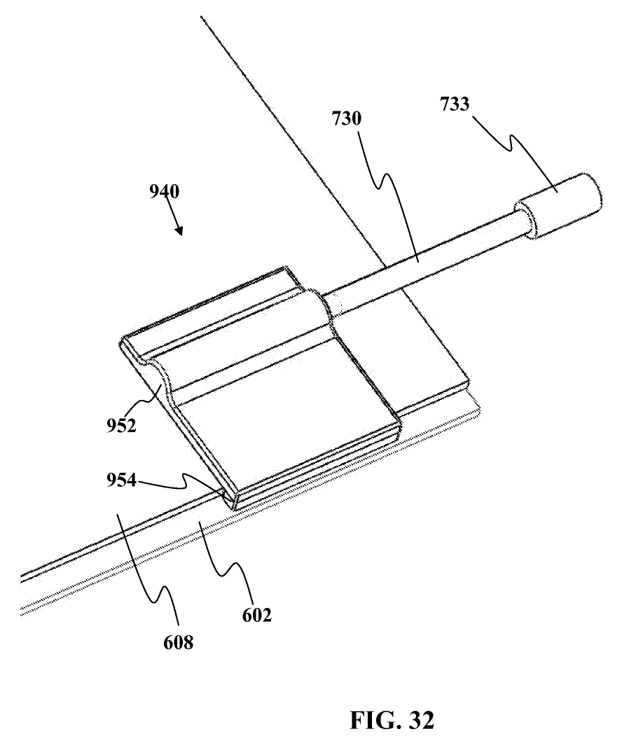

As seen in FIG. 32, the combined portions 950 and 952 define the connector 940 which may be located along the edge of the module layer 608. Other embodiments may locate the connector 940 (with or without lip portions 954 and 956) away from the actual edge of the module. Some embodiments may have the connector 940 configured to contact the side and/or the front of the upper module layer. The wire 730 may have a length from about 1 cm to about 100 cm. Optionally, wire 730 may have a length from about 5 cm to about 50 cm. Optionally, wire 730 may have a length from about 10 to about 30 cm.

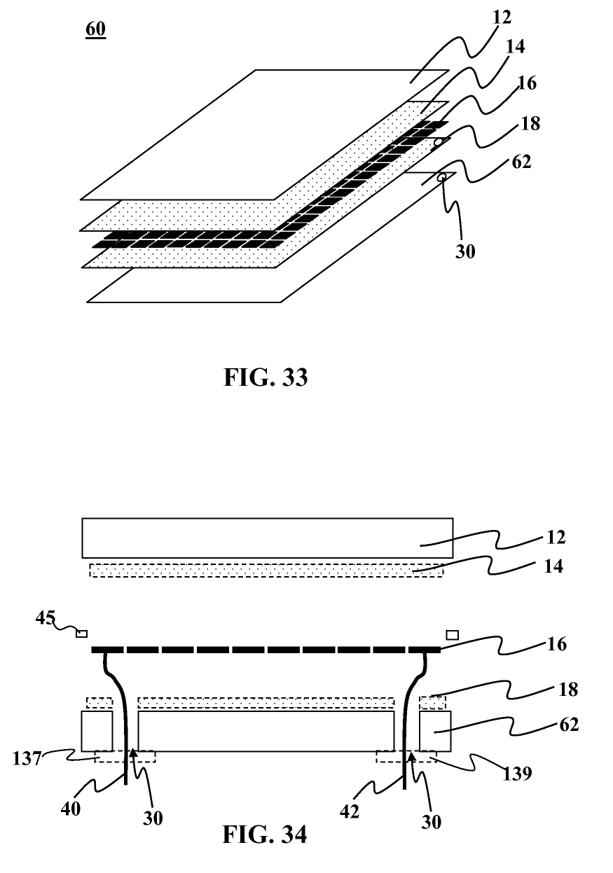

Referring now to FIGS. 33 and 34, it should also be understood that in some embodiments, a junction box 137 and 139 (shown in phantom) may be used over the openings 30 formed in the module layer(s). These embodiments may have openings through the back side module layer, instead of having the electrical leads exit from between the edges of the module. Any of the edge connector embodiments herein may be adapted for use with electrical leads that exit through a hole or opening in the module layer and not through the edge between module layers. The individual junction boxes 137 and 139 may be filled with pottant or other material to seal against the module back layer. Optionally, the individual junction boxes 137 and 139 may be non-central junction boxes, wherein only one electrical lead exits from each of the junction boxes. These junction boxes 137 and 139 may contain none, one, or more bypass diodes. The junction boxes 137 and 139 may be located only on the backside or optionally, a portion of it may extend along the backside of the module to at least a portion of the side surface of the module. Some may also extend along the side to the front side surface of the module. The module also include a moisture barrier around the perimeter of the module (not shown) similar that of other embodiments disclosed herein. As seen, some embodiments have the cells formed directly on the glass in which case one and/or both pottant layers 14 and 18 (shown in phantom) may become optional.

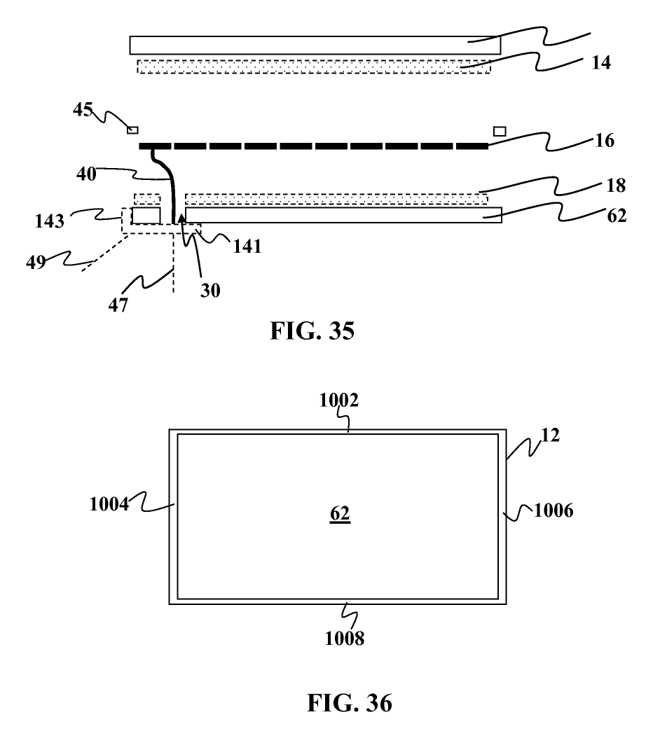

Referring now to FIG. 35, this embodiment shows that the junction box 141 covering opening 30 may be configured to one portion 143 that extends along at least a side portion of the back side layer 62. This helps to secure the housing or box 141 in place. If box 141 is located near a corner of the module, it may contact two side edges and the backside of the layer 62. This all helps to assist in retaining the box 141 in place. The wire extending out from the box or housing 141 may extend in the direction 47 or sideways as indicated by line 49.

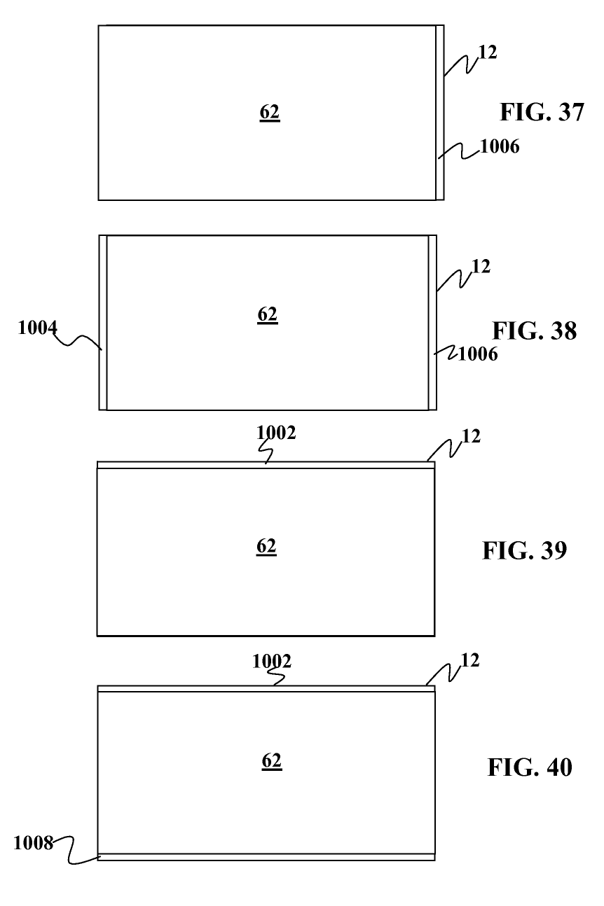

Referring now to FIGS. 36 through 40, various configurations of back layer 62 versus front layer 12 are shown. FIG. 36 shows that the back layer 62 is smaller in all four directions and thus edge portions 1002, 1004, 1006, and 1008 are all visible when viewing the module from the underside. This allows for the edge housings to fitted on one or more of these edge portions. FIG. 37 shows an embodiment where the layers 12 and 16 are sized and positioned to expose only one edge portion, which in this case is edge portion 1006. FIG. 38 shows an embodiment where the layers 12 and 16 are sized and positioned to expose two edge portions, which in this case are edge portions 1004 and 1006. FIG. 39 shows an embodiment where the layers 12 and 16 are sized and positioned to expose only one edge portion, which in this case is edge portion 1002. FIG. 40 shows an embodiment where the layers 12 and 16 are sized and positioned to expose two edge portions, which in this case are edge portions 1002 and 1008. By way of example and not limitation, each edge portion may have zero to one edge housings. Optionally, some edge portions may have two or more edge housings. Optionally, some edge portions may have three or more edge housing.

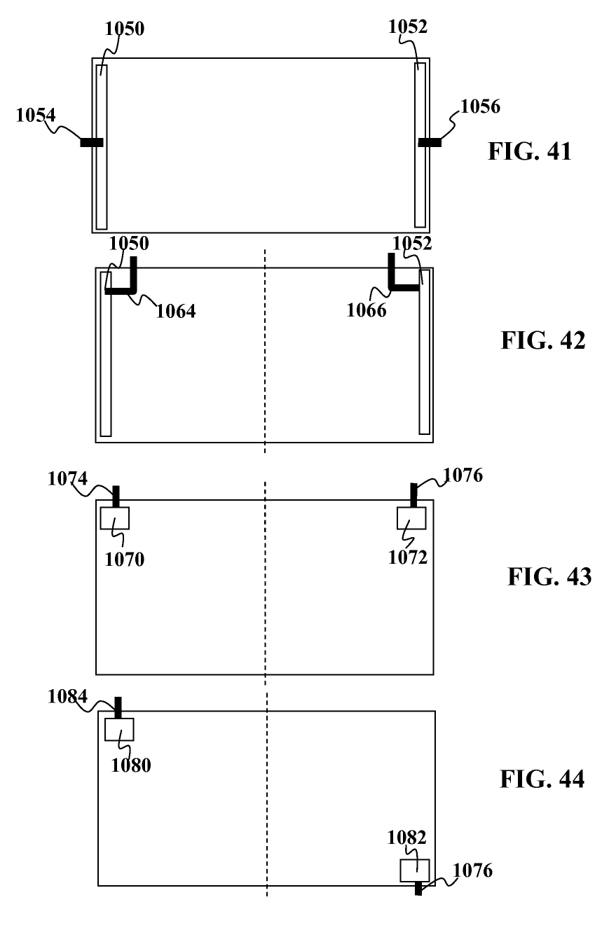

Referring now to FIG. 41 through 44, various embodiments are shown depicting internal electrical wiring from the first and last cell in a module. FIG. 41 shows a first cell 1050 and a last cell 1052. The wires 1054 and 1056 from those cells exit fairly directly, either out the edge or through openings in the module layer. FIG. 42 shows a first cell 1050 and a last cell 1052. The wires 1064 and 1066 from those cells may trace backward under one or more cells before exiting, either out the edge or through openings in the module layer. The wires 1064 and 1066 do not reach within a certain distance from the centerline 1069, which in this embodiment is 10% of the distance from the centerline 1069 to the edge (left or right) of the module. Optionally, they do no reach within 20% of the distance from the centerline 1069 to the edge (left or right) of the module. Optionally, they do no reach within 30% of the distance from the centerline 1069 to the edge (left or right) of the module. Optionally, they do no reach within 40% of the distance from the centerline 1069 to the edge (left or right) of the module. Optionally, they do no reach within 50% of the distance from the centerline 1069 to the edge (left or right) of the module. Optionally, they do no reach within 60% of the distance from the centerline 1069 to the edge (left or right) of the module. Optionally, they do no reach within 70% of the distance from the centerline 1069 to the edge (left or right) of the module. Optionally, they do no reach within 80% of the distance from the centerline 1069 to the edge (left or right) of the module. Optionally, they do no reach within 90% of the distance from the centerline 1069 to the edge (left or right) of the module. FIG. 43 shows a first cell 1070 and a last cell 1072. The wires 1074 and 1076 from those cells exit fairly directly, either out the edge or through openings in the module layer. FIG. 44 shows a first cell 1080 and a last cell 1082. The wires 1084 and 1086 from those cells exit fairly directly, either out the edge or through openings in the module layer.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, although glass is the layer most often described as the top layer for the module, it should be understood that other material may be used and some multi-laminate materials may be used in place of or in combination with the glass. Some embodiments may use flexible top layers or coversheets. By way of nonlimiting example, the backsheet is not limited to rigid modules and may be adapted for use with flexible solar modules and flexible photovoltaic building materials. Embodiments of the present invention may be adapted for use with superstrate or substrate designs. Details of modules with thermally conductive backplanes and heat sinks can be found in commonly assigned, co-pending U.S. patent application Ser. No. 11/465,783 (Attorney Docket NSL-089) filed Aug. 18, 2006 and fully incorporated herein by reference for all purposes. Other backsheet materials may also be used and is not limited to glass only embodiments. The housing of the connector could be made of any material by any method. The connector could be designed for hand assembly instead of automated assembly, leaving out locating features. The connector could be designed without the channel and holes to allow potting. The connector could be designed to allow two or more connectors to exit the solar module, and could include diode linked between the exiting conductors. Some embodiments may have lower surfaces 422 greater in area than the surface 424. Optionally, some embodiments may have surfaces 424 greater than surfaces 422. In one embodiment, both electrical leads or edge housings are on the same side of module. In another embodiment, they are on different sides. In a still further embodiment, they are diagonal from each other. In yet another embodiment, they are on opposing sides. Any of the embodiments herein may be adapted for framed and/or frameless modules. They may also be adapted for use with thin-film photovoltaic devices or silicon based photovoltaic devices.

Although the examples provided herein discuss the edge housing for use with a glass-glass modules, it should be understood that is may also be used with other photovoltaic modules such as but not limited to glass-foil and/or fully flexible modules. It should also be understood that embodiments of the edge exiting module may be configured so that the distance of internal wiring leading from the last cell to the exit from the module (either from an opening in the module layer or from an edge of the module) is no more than the distance from an edge of the cell to a centerline of the module. Optionally, the wire or ribbon from the connecting cell is less than 90% of the distance from an edge of the cell to a centerline of the module. Optionally, the wire or ribbon from the connecting cell is less than 80% of the distance from an edge of the cell to a centerline of the module. Optionally, the wire or ribbon from the connecting cell is less than 70% of the distance from an edge of the cell to a centerline of the module. Optionally, the wire or ribbon from the connecting cell is less than 60% of the distance from an edge of the cell to a centerline of the module. Optionally, the wire or ribbon from the connecting cell is less than 50% of the distance from an edge of the cell to a centerline of the module. Optionally, the wire or ribbon from the connecting cell is less than 40% of the distance from an edge of the cell to a centerline of the module. Optionally, the wire or ribbon from the connecting cell is less than 30% of the distance from an edge of the cell to a centerline of the module.

Optionally, the wire or ribbon from edge housing is less than 90% of the distance from an edge of the module to a centerline of the module. Optionally, the wire or ribbon from the edge housing is less than 80% of the distance from the edge housing on the module to a centerline of the module. Optionally, the wire or ribbon from the edge housing is less than 70% of the distance from the edge housing on the module to a centerline of the module. Optionally, the wire or ribbon from the edge housing is less than 60% of the distance from the edge housing on the module to a centerline of the module. Optionally, the wire or ribbon from the edge housing is less than 50% of the distance from the edge housing on the module to a centerline of the module. Optionally, the wire or ribbon from the edge housing is less than 40% of the distance from the edge housing on the module to a centerline of the module.

Optionally, the total length of the wire connection from edge housing to edge housing is about 60 cm or less. Optionally, the total length of the wire connection from edge housing to edge housing is about 50 cm or less. Optionally, the total length of the wire connection from edge housing to edge housing is about 40 cm or less. Optionally, the total length of the wire connection from edge housing to edge housing is about 30 cm or less. Optionally, the total length of the wire connection from edge housing to edge housing is about 20 cm or less. This total length of wire may be comprised of a single wire 900 or from multiple wires used to span the distance. Optionally, the total length of wire from edge housing to edge housing is less than 50 cm for module of an active area of at least 1 m². Optionally, the total length of wire from edge housing to edge housing is less than 50 cm for module of an active area of at least 2 m². Any of the above may be associated with a large module of at least 1 m² active area. This distinguishes from very small solar modules. Optionally, any of the above may be associated with a large module of at least 1.5 m² active area. Optionally, any of the above may be associated with a large module of at least 2.0 m² active area.

In another embodiment, the straight line distance of wire connection from an edge housing on one module to the edge housing on an adjacent module (which it is electrically connected) is about 60 cm or less for a module of at least 100 W output at AM1.5G. Optionally, the straight line distance of wire connection from an edge housing on one module to an edge housing on an adjacent module is about 50 cm or less for a module of at least 100 W output at AM1.5G. Optionally, the straight line distance of wire connection from an edge housing on one module to an edge housing on an adjacent module is about 40 cm or less for a module of at least 100 W output at AM1.5G. Optionally, the straight line distance of wire connection from an edge housing on one module to an edge housing on an adjacent module is about 30 cm or less for a module of at least 100 W output at AM1.5G. Optionally, the straight line distance of wire connection from an edge housing on one module to an edge housing on an adjacent module is about 20 cm or less for a module of at least 100 W output at AM1.5G. Optionally, any of the above may be associated with a large module of at least 80 W output at AM1.5G. Optionally, any of the above may be associated with a large module of at least 125 W output at AM1.5G.

Optionally, any of the above may be associated with a large module of at least 150 W output at AM1.5G. Optionally, any of the above may be associated with a large module of at least 175 W output at AM1.5G. Optionally, any of the above may be associated with a large module of at least 200 W output at AM1.5G.

Optionally, the length of the wire from edge housing on one module to edge housing on an adjacent module is less than ¼ distance from location of edge housing to the centerline of the module it is on. This may be a vertical or horizontal center line. Optionally, it is to the furthest centerline. Optionally, the length of the wire from edge housing on one module to edge housing on an adjacent module is less than ⅓ distance from location of edge housing to the centerline of the module it is on. Optionally, the length of the wire from edge housing on one module to edge housing on an adjacent module is less than ½ distance from location of edge housing to the centerline of the module it is on. Optionally, any of the above may be associated with a large module of at least 80 W output at AM1.5G. Optionally, any of the above may be associated with a large module of at least 125 W output at AM1.5G. Optionally, any of the above may be associated with a large module of at least 150 W output at AM1.5G. Optionally, any of the above may be associated with a large module of at least 175 W output at AM1.5G. Optionally, any of the above may be associated with a large module of at least 200 W output at AM1.5G. Optionally, instead of length of wire, the distance above the straightline distance from edge housing on one module to closest edge housing on an adjacent module.

Optionally, the location of the connection between wires from edge housings may be asymmetric (one wire longer than other), symmetric (wires same length), or completely on one or the other (no wire from one housing).

Optionally, internal cabling exiting the module does not go under another cell. Optionally, this internal cabling from a first cell or last cell does not go under one other cell. Optionally, this internal cabling exiting the module does not exceed a length of 100 cm. Optionally, this internal cabling exiting the module does not exceed a length of 75 cm. Optionally, this internal cabling exiting the module does not exceed a length of 50 cm. Optionally, this internal cabling exiting the module does not exceed a length of 40 cm. Optionally, this internal cabling exiting the module does not exceed a length of 30 cm. Optionally, this internal cabling exiting the module does not exceed a length of 20 cm. Optionally, internal cabling exiting the module does not exceed a length of ½ the length of the external cabling. Optionally, internal cabling exiting the module does not exceed a length of ⅓ the length of the external cabling.

In some embodiment, the edge housing is fully under the module, extending out over the side, and or with X distance from the edge. This distance X may be 10 cm from the closest edge of the cell it is electrically coupled. Optionally, this distance X may be 20 cm from the closest edge of the cell it is electrically coupled.

Optionally, the lip of the edge housing does not need to be used with the staggered glass of FIGS. 36-40. As long as the lip contacts two surfaces or sides of the glass, it may be sufficient. Some embodiments of the edge housing may be right at the corner and touch three sides (side, side, bottom glass layer).

The rounded bump is moved away from the staggered edge to allow for flat mounting surface near mounting rails which support the modules. As seen, the rounded bump in the portion 952 is away from the centerline and towards a portion away from the edge of the module to provide space for the mounting rail. Optionally, the portion 952 may or may not have a hole to allow for pottant to be injected in or to allow pottant to flow out.

Furthermore, those of skill in the art will recognize that any of the embodiments of the present invention can be applied to almost any type of solar cell material and/or architecture. For example, the absorber layer in solar cell 10 may be an absorber layer comprised of silicon, amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates. It should also be understood that between a transparent module layer and a backside module layer may also include intervening layers that may be between 1) the cells and the transparent module layer and/or 2) the cells and the backside module layer.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc. . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. Specifically, U.S. Provisional Applications 60/942,993 filed Jun. 8, 2007 and 60/968,870 filed Aug. 29, 2007 are fully incorporated herein by reference for all purposes.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A photovoltaic module comprising:
a plurality of photovoltaic cells positioned between a transparent module layer and a backside module layer.

2. A photovoltaic module comprising:
a plurality of photovoltaic cells positioned between a transparent module layer and a backside module layer;
at least one electrical housing positioned along an edge of the module to allow electrical connection to the photovoltaic cells by way of a first electrical lead in the housing that exits between the transparent module layer and the backside module layer,
wherein the housing is located beneath the transparent module layer and is positioned so as not to contact a front side surface of the transparent module layer.

3. The module of claim 1 wherein the module is a frameless module.

4. The module of claim 1 wherein the backside module layer, transparent module layer, and the cells therebetween are coupled together without a frame extending around a perimeter of the module layers.

5. The module of claim 1 comprises a glass-glass module.

6. The module of claim 1 wherein one edge of the transparent module layer extends beyond a corresponding edge of the backside module layer.

7. The module of claim 1 wherein one edge of the transparent module layer extends beyond a corresponding edge of the backside module layer by about 2 mm to about 10 mm.

8. The module of claim 1 wherein one edge of the transparent module layer extends beyond a corresponding edge of the backside module layer, while all other edges remain substantially flush with corresponding edges of the transparent module layer.

9. The module of claim 1 wherein transparent module layer comprise a larger sheet of material than the backside module layer so that at least one edge of the transparent module layer extends beyond a corresponding edge of the backside module layer.

10. The module of claim 1 further comprising a second electrical housing positioned along an edge of the module to allow electrical connection to the photovoltaic cells by way of a second electrical lead in the housing.

11. The module of claim 10 wherein the first electrical lead or the second electrical lead comprises of a flat wire or ribbon.

12. The module of claim 10 wherein the first electrical lead or the second electrical lead comprises of a flat aluminum wire.

13. The module of claim 10 wherein the first electrical lead or the second electrical lead comprises of a length no more than about 2× a distance from one edge of the module to an edge of a closest adjacent module.

14. The module of claim 10 wherein the first electrical lead or the second electrical lead has a length no more than about 30 cm.

15. The module of claim 1 wherein the module is in landscape configuration defined by a long dimension and a short dimension, wherein the first electrical lead extends from the module along the short dimension.

16. The module of claim 1 wherein the module is in landscape configuration defined by a long dimension and a short dimension, wherein the first electrical lead extends from the module along the long dimension, closer to one end of the module than a middle of the module.

17. The module of claim 10 wherein the first electrical lead extends outward from one edge of the module and the second electrical lead extend outward from the same edge of the module.

18. The module of claim 10 wherein the first electrical lead extends outward from along one edge of the module and the second electrical lead extends outward from a different edge of the module.

19. The module of claim 10 wherein the first housing and the second housing each define an interior space configured to accommodate encapsulant material injected into the space to form the moisture barrier.

20. The module of claim 10 wherein the first housing and the second housing r each have an opening allowing encapsulant material to be injected into the connecter to form a moisture barrier after the connecter is mounted onto the module.
